(19) United States
(12) Patent Application Publication
(10) Pub. No.: US 2023/0174254 A1
(43) Pub. Date: Jun. 8, 2023

(54) SOLAR SHEETS WITH IMPROVED LIGHT COUPLING AND METHODS FOR THEIR MANUFACTURE AND USE

(71) Applicant: MICROLINK DEVICES, INC., Niles, IL (US)

(72) Inventors: Christopher Youtsey, Libertyville, IL (US); Mark Osowski, Vernon Hills, IL (US); Rao Tatavarti, Mount Prospect, IL (US)

(21) Appl. No.: 17/962,101

(22) Filed: Oct. 7, 2022

Related U.S. Application Data
(60) Provisional application No. 63/253,936, filed on Oct. 8, 2021.

(51) Int. Cl. B64U 50/31; H01L 31/0392; H01L 31/054

(52) U.S. Cl. CPC B64U 50/31; H01L 31/03926; H01L 31/0543; B64U 30/10

(57) ABSTRACT

Systems and methods are presented including solar cells or solar sheets having textured coversheets that provide increased light collection efficiency. Some embodiments include a textured solar sheet configured for installation on a surface of a UAV or on a surface of a component of a UAV. The textured solar sheet includes a plurality of solar cells and a polymer layer to which the plurality of solar cells are attached. Some embodiments include a kit for supplying solar power in a battery-powered or fuel cell powered unmanned aerial vehicle (UAV) by incorporating flexible, textured solar cells into a component of a UAV, affixing flexible, textured solar cells to a surface of a UAV, or affixing flexible, textured solar cells to a surface of a component of a UAV. The kit also includes a power conditioning system configured to operate the solar cells within a desired power range and configured to provide power having a voltage compatible with an electrical system of the UAV.

### CROSS REFERENCE TO RELATED APPLICATIONS

This application claims priority to U.S. Provisional Application No. 63/253,936, filed Oct. 8, 2021, the entire contents of this application being incorporated herein by reference.

### STATEMENT OF GOVERNMENT INTEREST

This invention was made with government support under Contract No. FA8730-19-P-0042 awarded by the Air Force Research Laboratory (AFRL). The government has certain rights in this invention.

### BACKGROUND

Many of the current generation of unmanned aerial vehicles (UAVs) are electrically powered. Most electrically powered small UAVs are battery-powered, such as the RAVEN, WASP III, and PUMA AE by AeroVironment, Inc. of Monrovia, Calif., SCANEAGLE by Boeing of Seattle, Wash., and the MAVERIC UAS by PRIORIA ROBOTICS of Gainesville, Fla. The endurance (i.e., total flight time of the vehicle with a full battery charge) of the current generation of small, electrically-powered unmanned aerial vehicles (UAVs) is limited by power consumed by the UAV and the energy storage capacity of the battery. For example, the endurance of the RAVEN UAV is limited to approximately 90 minutes of flight time. The limit on endurance of small UAVs reduces the operational effectiveness of the small UAVs because it limits the time the UAV can spend over a target of interest, and limits a distance range for targets.

A High-Altitude Long Endurance (HALE) UAV is an airborne vehicle which functions optimally at high altitude (e.g., at least 30,000 feet or 9,000 meters above sea level) and is capable of flights which last for considerable periods of time (e.g., greater than 24 hours) without recourse to landing. Generally, recent generations of HALE UAVs are capable of operating at high altitudes and longer flight times than prior generations. Some examples of HALE UAVs are GLOBAL HAWK by Northrop Grumman Corp. of Falls Church, Va., ALTUS II by General Atomics Aeronautical Systems Inc. of San Diego, Calif., PHANTOM EYE by Boeing of Seattle, Wash., and ZEPHYR by Airbus Defense and Space of Farnborough, UK. Recently some HALE UAVs, such as ZEPHYR, have been produced that can fly at a maximum altitude 70,000 feet. For some types of HALE UAVs the need to refuel can set a limit on the maximum flight time or endurance of the UAV. For some types of HALE UAVs that are powered exclusively by solar cells, a reduction in the mass of the solar cells could increase the payload capacity of the HALE UAV.

### SUMMARY

A solar sheet is provided. The solar sheet includes thin film solar cells and a flexible polymer sheet disposed across a light receiving surface of the plurality of thin film solar cells. The flexible polymer sheet has a plurality of prismatic structures formed in the top surface thereof to improve light collection efficiency. A bottom surface of the flexible polymer sheet is disposed across the plurality of solar cells.

A method of manufacturing a thin film solar sheet is provided. The method includes forming a plurality of prismatic structures on a first side of a flexible polymer sheet. The method also includes attaching a second side of the flexible polymer sheet that opposes the first side of the flexible polymer sheet to a plurality of thin film solar cells.

A flexible device to enhance light collection efficiency of a plurality of thin film solar cells is provided. The flexible device includes a flexible polymer sheet having a textured top side and a bottom side. The textured top side includes prismatic structures formed therein to improve light collection efficiency. The bottom side is configured to overlay a plurality of thin film solar cells.

A method of improving flight time in an unmanned aerial vehicle (UAV) is provided. The method includes providing a component of a UAV. The component includes a plurality of thin film solar cells and a flexible polymer sheet disposed across a light receiving surface of the plurality of thin film solar cells. The flexible polymer sheet has prismatic structures formed in a top surface thereof to improve light collection efficiency and increase power production in the plurality of thin film solar cells to enable longer flight times for the UAV. The flexible polymer sheet has a bottom surface disposed across the plurality of thin film solar cells. The method further includes providing a power conditioning system configured to operate the plurality of thin film solar cells within a desired power range and configured to provide power in the form of a voltage compatible with an electrical system of the UAV. The method further includes installing the component in the UAV. The method further includes connecting the power conditioning system with the electrical system of the UAV.

An unmanned aerial vehicle (UAV) is provided. The UAV includes a solar sheet installed on a surface of the UAV or on a surface of a component of the UAV. The solar sheet includes a plurality of thin film solar cells and a flexible polymer sheet disposed across a light receiving surface of the plurality of thin film solar cells. The flexible polymer sheet has a plurality of prismatic structures formed in a top surface thereof to improve light collection efficiency. The flexible polymer sheet includes a bottom surface disposed across the plurality of solar cells. The UAV includes a power conditioning system configured to operate the plurality of thin film solar cells within a desired power range and configured to provide power in the form of a voltage compatible with an electrical system of the UAV.

### BRIEF DESCRIPTION OF THE DRAWINGS

The foregoing and other objects, features and advantages of the invention will be apparent from the following description, and from the accompanying drawings, in which like reference characters refer to the same parts throughout the different views. The drawings illustrate principles of the invention and are not to scale.

FIG. 1A illustrates a cross-sectional schematic view of a thin-film solar sheet with enhanced light collection efficiency in accordance with various embodiments described herein.

FIG. 1B is a schematic illustration of a cross-sectional view of the thin-film solar sheet demonstrating the function of prismatic structures in improving light collection efficiency.

FIG. 2A depicts a perspective view of a kit including a plurality of solar cells installed on an unmanned aerial vehicle (UAV), in accordance with an embodiment.

FIG. 2B schematically depicts a plan view of a wing component of a UAV with installed solar cells, in accordance with an embodiment.

FIG. 3 is a plot illustrating the improvement in solar power collection as a function of time of day (i.e., as a function of changing sun elevation) for embodiments of devices described herein.

FIG. 4 is a plot illustrating transmission efficiency as a function of zenith angle for conventional solar cell coversheets and solar cell coversheets and devices of the present disclosure.

FIG. 5 is a plot illustrating the external quantum efficiencies of a triple-junction (3J) solar cell including a conventional coversheet vs. a 3J solar cell including a coversheet as described in embodiments herein.

FIG. 6 is a plot illustrating the current-voltage (I-V) response as a function of solar zenith angle for a 3J solar cell including a conventional coversheet vs. a 3J solar cell including a coversheet as described in embodiments herein.

FIG. 7 is a plot illustrating the ratio of solar cell current as a function of solar zenith angle for a 3J solar cell including a conventional coversheet vs. a 3J solar cell including a coversheet as described in embodiments herein.

FIG. 8 illustrates the recapture and retroreflection of light in a solar cell according to various embodiments described herein.

FIG. 9 illustrates the simulated transmittance of light as a function of solar zenith angle and solar azimuthal angle for solar cell coversheets having pyramidal prismatic structures according to various embodiments described herein.

FIGS. 10A-10D are plots illustrating simulated transmission as functions of solar elevation angle and solar azimuthal angle for prismatic coversheets according to various embodiments of this disclosure wherein the prismatic structures have sidewall angles of 15°, 45°, 60°, and 75°, respectively.

FIG. 11 illustrates an embodiment of a coversheet design including linear prismatic structures according to various embodiments of the present disclosure.

FIG. 12 illustrates the simulated transmittance of light as a function of solar elevation angle and solar azimuthal angle for solar cell coversheets having linear prismatic structures according to various embodiments described herein.

FIGS. 13A-13B illustrate scanning electron microscope (SEM) images at different magnification factors of a fluorinated ethylene propylene coversheet including a plurality of prismatic structures produced by embossing according to various embodiments described herein.

FIG. 14 illustrates the transmissivity as a function of wavelength of light as measured for several materials.

FIG. 15 illustrates a scanning laser confocal microscope image and related table of values for an ethylene chlorotrifluoroethylene (ECTFE) coversheet including a plurality of prismatic structures produced by embossing according to various embodiments described herein.

FIG. 16 is a plot illustrating comparative light collection efficiency as a function of incident light angle for a conventional solar cell vs. a solar cell including pyramidal prismatic structures according to various embodiments described herein.

FIG. 17 is a plot illustrating comparative light collection efficiency as a function of incident light angle for a conventional solar cell vs. a solar cell including linear prismatic structures according to various embodiments described herein.

FIG. 18 is a plot illustrating the measured current-voltage characteristic for a same solar cell before and after application of a coversheet including a plurality of prismatic structures according to various embodiments described herein.

FIG. 19A is a plot illustrating simulated net transmittance as a function of incident light angle for conventional solar cells and solar cells including linear prismatic structures according to the present disclosure.

FIG. 19B is a plot illustrating experimental measurements of light collection efficiency as a function of incident light angle for conventional solar cells and solar cells including linear prismatic structures according to the present disclosure.

FIG. 20 is a plot illustrating power output measured outdoors under solar illumination for a conventional solar cell and for a solar cell including prismatic structures according to the present disclosure as a function of time of day. The plot also illustrates percentage improvement for the solar cell according to this disclosure over the conventional solar cell.

FIG. 21 is a block diagram of a power conditioning circuit (PCC) in accordance with an embodiment.

FIG. 22A is a block diagram of a power conditioning system in a first mode in which the solar cells provide supplemental power for a UAV.

FIG. 22B is a block diagram of the power conditioning system in a second mode in which the solar cells provide operating power for the UAV and charge an energy storage device of the UAV system.

FIG. 23A schematically depicts a side cross-sectional view of example solar sheet, in accordance with some embodiments.

FIG. 23B schematically depicts a detail of the solar sheet of FIG. 23A.

FIG. 24 illustrates a cross-sectional schematic view of a thin-film solar sheet with enhanced light collection efficiency in accordance with various embodiments described herein.

FIG. 25 is a perspective view of a solar sheet including a plurality of solar cells illustrating the flexibility of the solar cells and of the solar sheet, in accordance with an embodiment.

FIG. 26 schematically depicts a plan view of an exemplary solar cell, in accordance with an embodiment.

FIG. 27 is a block diagram of a method of increasing endurance of a battery-powered or fuel cell powered UAV in accordance with an embodiment.

FIG. 28 is a block diagram of another method of increasing endurance of a battery-powered or fuel cell powered UAV in accordance with an embodiment.

FIG. 29A schematically depicts a top view of an adhesive layer that includes cutouts smaller than corresponding solar cells, in accordance with some embodiments.

FIG. 29B schematically depicts a top view an adhesive layer that includes cutouts larger than corresponding solar cells, in accordance with some embodiments.

FIG. 30A schematically depicts a side cross-sectional view of an example solar sheet A, as taught herein.

FIG. 30B is a graph of percentage masses of various layers in example solar sheet A, as taught herein.

FIG. 31 is a graph of percentage masses of various layers in an example solar sheet B, as taught herein.

### DETAILED DESCRIPTION

In accordance with various embodiments described herein, systems and methods of the present disclosure include solar sheet devices having a textured coversheet that increases light collection efficiency. The light collection efficiency is particularly improved over that of conventional solar cells or solar sheets for light arriving from high incident angles. The improved collection efficiency results in, for example, greater instantaneous power production as well as greater accumulated power production over the course of a period of time, e.g., one day or multiple days.

While the advantages of greater light collection efficiency are relevant in any solar cell or solar sheet system, greater light collection efficiency in the field of UAVs can improve endurance of the UAVs. The endurance of small UAVs and some HALE UAVs is typically limited due to the operational power requirements for the UAV and the limited energy storage capacity of the battery (e.g., the endurance of the RAVEN small UAV is 60-90 minutes). Increasing endurance enhances the operational effectiveness of a small UAVs and HALE UAVs because a UAV with enhanced endurance can spend more time over the target of interest and/or can travel to targets further away. Adding additional batteries may increase the endurance of a UAV; however the additional batteries would substantially increase the weight of the UAV, thereby reducing its payload or degrading its aerodynamic characteristics.

In many use cases, light (e.g., sunlight) is incident upon solar sheets installed on a UAV at high incident angles, e.g., greater than 60°, particularly for flights during the morning or evening hours or for flights at high latitudes. When light strikes an interface between two media with different refractive indices, reflection and transmission of light at the interface is described by the Fresnel equations. According to these equations, the reflection and transmission of light has an angular dependence, and the light transmission drops significantly and approaches zero as the incident angle approaches 90 degrees. Thus, conventional solar sheets experience reflective losses at any air-material interface. Systems and methods described herein include prismatic structures designed to reduce Fresnel losses at the air-material interface.

For a variety of solar cell applications, it is advantageous to improve efficient collection of light at high zenith angles. For example, solar-powered stratospheric UAVs that are designed to fly continuously for multiple weeks can benefit from more efficient light collection at high zenith angles at the morning sun break (especially at high latitudes). In addition, efficient collection of light at high zenith angles provides additional energy harvesting during the day. Solar sheets and flexible coversheets of the present disclosure provide marked improvement in collection of light at high zenith angles.

One of the problems addressed by some embodiments described herein is how to substantially increase the endurance of a UAV (e.g., a small battery-powered or fuel cell powered UAV such as the RAVEN or a HALE UAV) without substantially increasing its size or weight. Some embodiments address this problem by providing a kit to equip a UAV with lightweight, flexible, high efficiency solar cells (e.g., one or more solar cell strings or sheets of solar cells) that supply additional power to the UAV, thereby significantly increasing the endurance of the UAV as compared to a UAV without solar cells. Other embodiments address this problem by providing one or more solar sheets to be installed on a UAV either after the UAV has been produced or during production. Because the solar cells have relatively small mass per unit area, they do not add significant weight to the UAV. In some embodiments, the solar cells have a high specific power (power to mass ratio) providing significant power generation for relatively little added weight. For both small UAVs (e.g., portable UAVs that may be transported or deployed by a single person in the field) and HALE UAVs it is particularly important that the solar cells do not significantly increase the overall weight of the UAV, which could degrade the performance of the UAV and decrease its endurance.

For solar powered UAVs, a payload capacity of the UAV can be increased by replacing solar cells currently used in the UAV with solar cells or solar sheets capable of generating more power per unit mass of the solar cell or solar sheet. Some solar powered UAVs that incorporate higher specific power solar cells or higher specific power solar sheets can have increased endurance. Higher specific power solar cells and higher specific power solar sheets may enable more solar cells and solar sheets to be incorporated into a UAV without significantly increasing the weight of the UAV.

Systems and methods described herein are not limited to use with aerial vehicles but can also be used in conjunction with ground-based applications. The disclosed systems and methods are particularly advantageous in applications where the surface of the solar panels does not track the motion of the sun. Such applications can include fixed-mount solar installations or portable solar sheets that can be laid on the ground or draped over a human or object.

As used herein, the term “small UAV” includes portable UAVs that may be carried by a single person. The term small UAV includes what may be referred to elsewhere as micro UAVs and mini UAVs and larger portable UAVs. Some non-limiting examples of small UAVs include the RQ-11B RAVEN UAV system with a weight of 1.9 kg and a wingspan of 1.4 m, the WASP Micro Air Vehicle (MAV) with a weight of 0.43 kg and a wingspan of 72 cm, and the RQ-20A PUMA with a weight of 5.9 kg and a wingspan of 2.8 m, the MAVERIC UAV with a 72 cm in wingspan and a loaded weight of about 1.1 kg, and the SCANEAGLE with a 3.1 m wingspan and an 18 kg.

As used herein, the term “HALE UAV” refers to an aircraft that functions at high altitude (i.e., greater than approximately 30,000 feet or 9,000 meters) and is capable of flights which last for considerable periods of time (e.g., longer than approximately 18 hours) without recourse to landing. Some non-limiting examples of HALE UAVs include, but are not limited to the GLOBAL HAWK, ALTUS II, PHANTOM EYE, and ZEPHYR UAVs.

As used herein, the term “areal mass” refers to mass per unit area. For example, the areal mass of a solar cell is the mass of solar cell per unit area of the solar cell. As another example, the areal mass of a solar sheet is the mass of solar sheet per unit area of the solar sheet.

As used herein, the term “areal power” refers to power produced per unit area. For example, the areal power of a solar cell is the power produced by the solar cell under a specified illumination divided by the area of the solar cell. As another example, the areal power of a solar sheet is the power produced by the solar sheet under a specified illumination divided by the area of the solar sheet.

As used herein, the term “specific power” refers to the power produced per unit mass. For example, the specific power of a solar cell is the power produced by the solar cell under a specified illumination divided by the mass of the solar cell. As another example, the specific power of a solar sheet is the power produced by the solar sheet under a specified illumination divided by the mass of the solar sheet. The specific power can also be defined as the areal power divided by areal mass.

As used herein, the term “solar sheet” refers to a plurality of solar cells and one or more polymer layers to which the solar cells are affixed or attached. The solar sheet can also include interconnects that electrically connect at least some of the plurality of solar cells. The solar sheet can also include an adhesive that adheres the solar cells to the one or more polymer layers. The solar sheet can also include an adhesive to adhere the solar sheet to an underlying surface (e.g., a surface of a component of an UAV to which the solar sheet is to be attached). The solar sheet can be flexible to conform to an underlying rounded surface (e.g., the surface of a wing or the surface of a fuselage of a UAV).

As used herein, the term “zenith angle” refers to the angle between the zenith and the center of the sun's disc. The zenith angle represents the sun's apparent altitude and is a complementary angle to the “elevation angle.” The elevation angle as used herein refers to the angle between the horizon and the center of the sun's disc. As an example, the zenith angle is approximately 90° and the elevation angle is approximately 0° during a sunrise or sunset. As used herein, “textured” refers to a surface upon which regular, patterned, random, or periodic structures are formed for the purpose of improving light collection efficiency through the surface.

As used herein, “disposed on” or “disposed over” is not limited to objects in direct contact with but can also encompass a structural relationship including intervening layers.

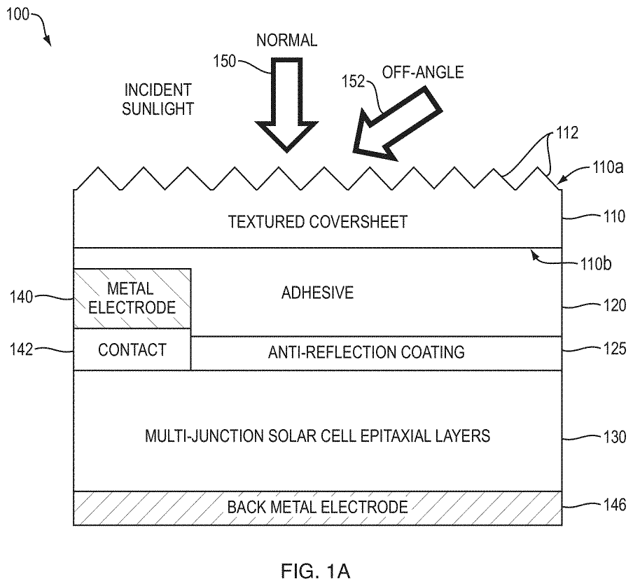

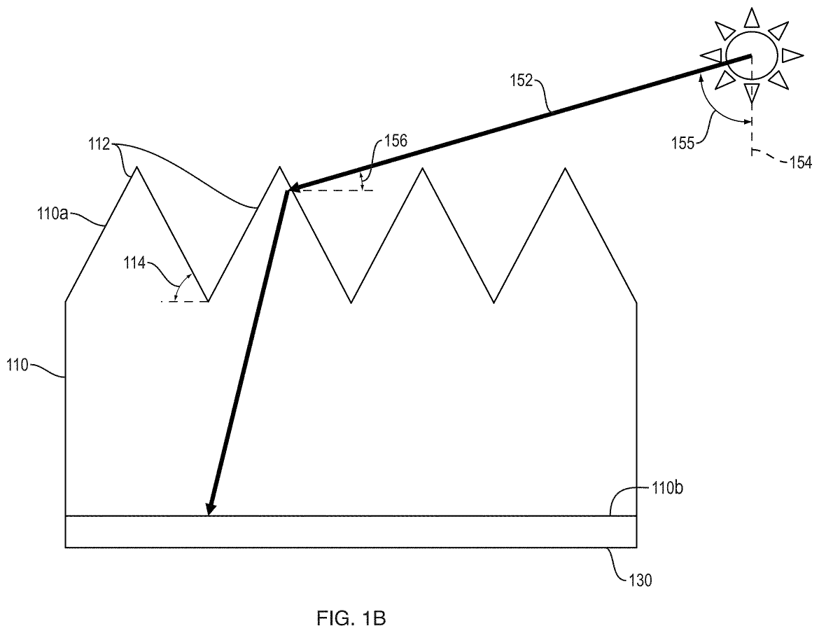

FIG. 1A illustrates a solar sheet 100 with improved light collection efficiency in accordance with various embodiments described herein. The solar sheet 100 includes a flexible coversheet 110 (which in some embodiments can be a polymer sheet) including a textured top surface 110a having surface features or structures. The surface features of the textured top surface 110a can include prismatic structures 112 formed in a first or top surface 110a of the coversheet 110 that forms an air-material interface. The solar sheet 100 also includes an anti-reflection coating 125, one or more thin film solar cells 130, one or more front metal electrodes 140, and one or more back metal electrodes 146. A second or bottom surface 110b of the flexible coversheet 110 is disposed over thin film solar cells 130 such that light enters the solar sheet 100 through the flexible coversheet 110 before impinging upon the solar cells 130. In some embodiments, the bottom surface 110b of the flexible coversheet 110 can be attached to the anti-reflection coating 125 using an adhesive layer 120. The one or more front metal electrodes 140 can connect to the one or more thin film solar cells 130 through a contact layer 142. The solar cells 130 can be disposed over the back metal electrode 146. The solar sheet 100 provides improved performance for light incident at high angles 152 relative to normal incidence 150 of the solar sheet 100 as described in greater detail below.

The outward-facing top surface 110a of the flexible coversheet 110 is textured using the prismatic structures 112 to improve transmission of light through the surface 110a and into the solar sheet 100. Each prismatic structure in the plurality of prismatic structures 112 has a particular geometry. The geometry of the prismatic structure can include an inverted prism structure, a non-inverted prism structure (i.e., the structure projects outward from the surface), a corner-cube (i.e., three-sided) prism structure, a pyramidal (i.e., four-sided) prism structure, a linear prism structure, a curvilinear prism structure, or any other suitable one-dimensional or two-dimensional shape. Here, “inverted” refers to a structure that is a depression into the surface while “non-inverted” refers to a structure that projects from the surface. The geometry of the prismatic structure can include curved walls, straight walls, or a combination of curved and straight elements. Embodiments of the textured surface 110a having one-dimensional or linear prismatic structures can include a sidewall topology that varies predominantly in one dimension (e.g., x-direction) across the surface 110a but that does not vary (within manufacturing variances) in the other dimension (e.g., y-direction). Embodiments of the textured surface 110a having two-dimensional prismatic structures can include a sidewall topology that varies in both dimensions (e.g., x and y dimensions). For polygonal prismatic structures, each structure can have three, four, five, or more facets. In some embodiments, the prismatic structures 112 can be at least partially defined by a sidewall angle 114 (see FIG. 1B), which is measured between sidewalls of the prismatic structures 112 and a plane defined by a base on the prismatic structures 112. For the prismatic structure 112 that is analogous to a conic solid such as a pyramid or cone, the sidewall angle 114 is equivalent to an apex angle between a base and a side surface of the conic solid. In some embodiments, the sidewall angle 114 can be in a range between 15° and 75°. In preferred embodiments, the sidewall angle 114 of each prismatic structure 112 can be in a range between 45° and 60°.

In general, the light capturing performance of prismatic structures at high zenith angle is improved relative to low zenith angles as the sidewall angle is increased. However, the transmission at normal incidence (i.e., zenith angle of 0°) can begin to degrade by several percent at high sidewall angles. In some embodiments, geometry of each prismatic structure in the plurality of prismatic structures 112 can be selected to improve light collection efficiency at particular ranges of zenith angles. For example, selection of large sidewall angle 114 may be advantageous for applications where the solar sheet is rarely expected to receive light at low zenith angle. In some embodiments, the geometry of each prismatic structure can be identical across the entire flexible coversheet. In some embodiments, the geometry of each of the prismatic structures 112 can be selected individually. In such embodiments, the variation in geometry of prismatic structures 112 can be random or patterned across the sheet. For example, the geometry (including sidewall angle 114) of the prismatic structures 112 can vary from one end of the solar sheet 100 to the other end or from the ends or perimeter to the middle. For example, the coversheet 110 may have prismatic structures 112 with large sidewall angle 114 at a first edge of the coversheet (e.g., the first edge will be mounted at a leading edge of the UAV wing) and prismatic structures 112 with smaller sidewall angle 114 at a second edge of the coversheet opposite the first edge (e.g., the second edge will be mounted at a trailing edge of the UAV wing). The change in sidewall angles transitioning from the first edge to the second edge can be monotonic or non-monotonic and continuous or punctuated. In some embodiments, it may be advantageous to provide a first subset of prismatic structures 112 having a first geometry on portions of the solar sheet intended to lie on flat portions of a UAV wing and a second subset of prismatic structures 112 having a second geometry on portions of the solar sheet intended to lie on curved portions of the UAV wing.

The flexible coversheet 110 can be formed of one or more polymer species. In various embodiments, the flexible polymer sheet 110 can be formed of one or more materials selected from the group of fluorinated ethylene propylene (FEP); ethylene tetrafluoroethylene (ETFE); ethylene chlorotrifluoroethylene (ECTFE); polychlorotrifluoroethylene (PCTFE); a copolymer of tetrafluoroethylene, hexafluoropropylene and vinylidene fluoride (THV); and polyethylene terephthalate (PET). The flexible coversheet 110 can include acrylic-based materials in some embodiments. The coversheet 110 can include glass materials in some embodiments. The coversheet 110 can include silicone materials such as polyimides or polydimethylsiloxane (PDMS) in some embodiments. In some embodiments, selection of polymer species for the flexible polymer sheet 110 can be driven by application-specific factors. For example, the polymer species can be selected based on light transmissivity at a particular wavelength or range of wavelengths in some embodiments. In some embodiments, the polymer species can be selected based upon the manufacturing process to be used in processing the flexible polymer sheet 110. Appropriate manufacturing processes can include thermal forming, molding, casting, forming, embossing, roughening, lithographic processes, or other suitable patterning processes. Some manufacturing processes may be more suitable for certain materials. For example, fluorinated ethylene propylene has a relatively high melting temperature (about 260° C.) that may make it difficult to effectively emboss. In some embodiments, roughening techniques can create a matte-like finish with random prismatic surface structures that can enhance light collection as disclosed herein.

The prismatic structures 112 can be described in terms of a characteristic dimension in some embodiments. For example, the characteristic dimension can be the distance from a peak of a first prismatic element to a peak of a neighboring prismatic element or can be a length or width dimension corresponding to a base of a pyramidal prismatic structure. The characteristic dimension can be a height of the prismatic structures 112. In some embodiments, the characteristic dimension of the prismatic structures 112 can be longer than a wavelength of incident light 152. In some embodiments, the height of each of the prismatic structures 112 can be in a range from approximately 10 micrometers to approximately 100 micrometers. For example, the height of one of the prismatic structures 112 can be measured from a tip or apex to a base of the prismatic structure. In some embodiments, the flexible coversheet 110 is configured to encapsulate the light receiving surface of the plurality of solar cells 130. In some embodiments, the flexible coversheet 110 can have a thickness in a range from approximately 10 micrometers to approximately 150 micrometers, or in a range from approximately 20 micrometers to approximately 50 micrometers. In some embodiments, the thickness of the flexible coversheet 110 can be selected to provide a desired mass density of the solar sheet. Some polymeric materials can be about half as dense as glass, which may impact the thicknesses selected based upon material type. In embodiments intended for space-based applications, the thickness of the flexible coversheet 110 can be, as a non-limiting example, in a range from 200 microns to 350 microns.

In some embodiments, the prismatic structures 112 can increase collection and power conversion efficiencies of the solar sheet 100 through improved optical coupling into the solar cell 100 by reducing the amount of light that is reflected at the air-material interface. FIG. 1B schematically illustrates the functioning of the prismatic structures 112 using a simplified system with the coversheet 110 and solar cells 130. Light 152 from the sun intercepts the air-material interface formed by the top surface 110a of the flexible coversheet 110 at an incident angle 156. The incident angle 156 is measured with respect to a flat surface formed by one or more solar cells 130 or with respect to a flat, planar coversheet 110 and not defined with respect to localized variations in the surface 110a of the coversheet 110 such as sidewalls of prismatic structures 120. The incident angle 156 is complementary to a zenith angle 155 of the sun in the sky. The zenith angle 155 is measured with respect to the imaginary zenith line 154 representing the sun being “directly overhead.” The prismatic structures 112 formed in the top surface 110a refract the light and direct the light downward (whether on a simple optical path involving few refractions/reflections or a more complicated optical path involving many refractions/reflections) where it ultimately strikes the solar cells 130 and is converted into electrical current. Without the texturing provided by the prismatic structures, light 152 incident at very shallow incident angles 156 would be reflected from the top surface 110a of the flexible coversheet 110 as provided by the Fresnel transmittance and reflectance equations. If reflected, the light 152 will not intercept the solar cells 130 and cannot be converted into electrical charge. The use of prismatic structures on the surface 110a of the flexible sheet 110 can prevent reflection and increase capture of light at shallow angles.

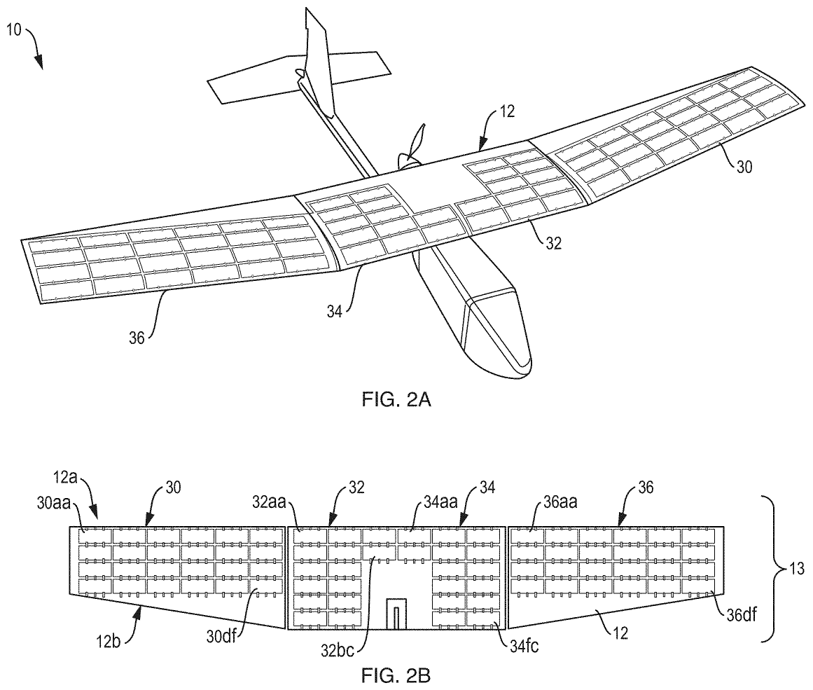

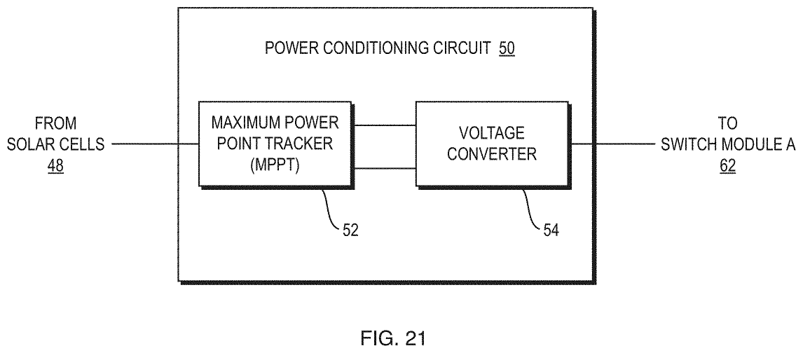

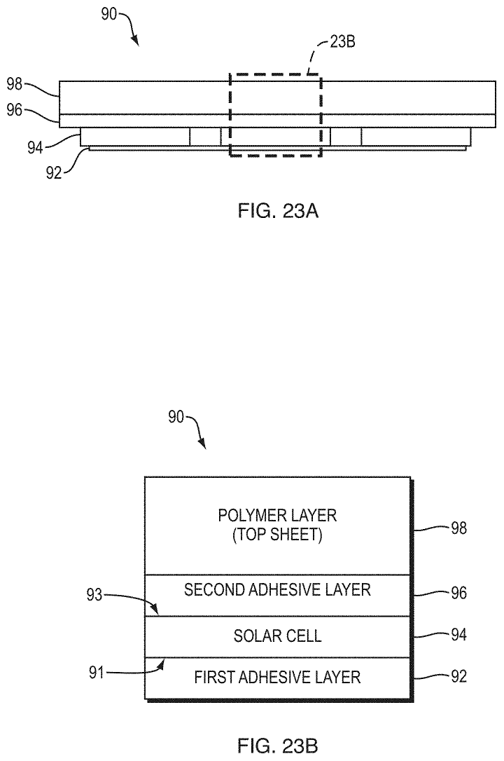

In some embodiments, a kit including solar cells or a solar sheet with the textured flexible solar sheet 110 (e.g., an embodiment of solar sheet 100) and a power conditioning system is used to increase endurance of a UAV. For example, FIG. 2A schematically depicts solar sheets 30, 32, 34, 36 of a kit mounted on a UAV 10 that includes a battery power system. As shown, high efficiency flexible solar sheets 30, 32, 34, 36 have been mounted on a surface of the UAV (e.g., the wing 12 of the UAV). The kit also includes a power conditioning system configured to operate the solar cells within a desired power range or at a maximum power point and configured to provide a specified voltage to an electrical system of the UAV (see FIGS. 21-23B below). The power conditioning system may also be configured to charge an energy storage device (e.g., battery) of the UAV system (see FIG. 23B below).

In some embodiments, the solar cells (e.g., one or more solar cell strings or solar sheets) may be installed on a surface of a previously-produced UAV (e.g., as a post-manufacturing modification). For example, solar sheets of a kit may be applied to the wings of a previously-produced UAV. The power conditioning system and associated electrical wiring may be installed in the wings and fuselage of the previously-produced UAV and interfaced with the existing electrical system of the previously-produced UAV. In some embodiments, the kit may be an upgrade, a retrofit, or an aftermarket kit for installation on a previously-produced UAV. In some embodiments, the solar cells (e.g., solar sheet(s)) may be mounted on or incorporated into a surface of a component of a UAV. The power conditioning system and associated electrical wiring (e.g., electrical harness) and connectors of the kit may be installed in the component. For example, FIG. 2B illustrates solar sheets 30, 32, 34, 36, each including multiple solar cells 30aa-30df, 32aa-32bc, 34aa-34fc, 36aa-36df, incorporated into a wing component 12 forming a wing assembly 13.

In some embodiments, the component with the solar sheet(s) (e.g., wing assembly 13) is used to replace a similar component in a previously-produced UAV as a post-manufacturing modification (e.g., as a retrofit or as an aftermarket modification). For example, a wing assembly including an installed kit may be used to replace a wing component in a previously-produced UAV.

In some embodiments, the component with the solar sheets (e.g., the wing assembly) is used during an initial manufacturing process of a UAV (e.g., as an upgrade). For example, a wing assembly with an installed kit may be incorporated into a UAV during initial manufacturing or assembly of the UAV as opposed to adding the solar cells and/or the power conditioning system to a previously-produced UAV.

Some embodiments may include an upgrade kit, a retrofit kit, or an aftermarket kit, for existing UAVs, such as the RAVEN UAV, the Wasp III UAV, the PUMA AE UAV, the MAVERIC UAS, GLOBAL HAWK, ALTUS II, PHANTOM EYE, and ZEPHYR. Different embodiments of kits can be used with different types or different models of UAVs.

In some embodiments, the solar sheets of the present disclosure can be adhered to a surface of a portion of a UAV. In some embodiments, the solar sheets can connect to a power conditioning system included in the UAV instead of being provided in a kit with a power conditioning.

In some embodiments, the UAV may be designed with parts and connections configured for the incorporation of flexible, light weight, high efficiency solar cells or flexible, light weight, high specific power solar sheets. Incorporation of the solar cells or solar sheets into the UAV design may result in better aerodynamics, more robust electrical connections, and reduced additional weight to due to the solar cells, packaging and wiring harness. Some embodiments include UAVs specifically designed for hybrid battery/solar operation, such as UAVs that are primarily battery powered with a secondary solar power system including flexible, lightweight, high-efficiency solar cells. Some embodiments include electric UAVs whose primary power source is solar and that include one or more rechargeable batteries or fuel cells.

In some embodiments, solar sheets are provided that are configured to adhere to a surface of a portion of a UAV. In some embodiments, embodiments of the solar sheets of the present disclosure can connect to a power conditioning system included in the UAV instead of being provided in a kit with a power conditioning. In some embodiments, the solar cells or solar sheets are used with a UAV that was designed to have solar power as its primary power source or run exclusively on solar power (e.g., the ZEPHYR HALE UAV).

In the embodiments depicted in FIGS. 2A and 2B, the solar cells can be incorporated into four solar sheets. In other embodiments, the solar cells may be incorporated into less than four solar sheets (e.g., one, two or three solar sheets) or may be incorporated into more than four solar sheets. In some embodiments, the kit includes one or more solar sheets and one or more strings of solar cells or individual solar cells not incorporated into solar sheets. In some embodiments, all of the plurality of solar cells are in the form of strings of solar cells or individual solar cells and not incorporated into solar sheets. Generally, the number of solar sheets to be installed on a UAV or included in a kit for a UAV depends on various factors, (e.g., size of the UAV, size of each solar sheets, how many solar cells are incorporated into each solar sheet). In some embodiments, the number of solar cells used on a UAV can be 100, 200, 300, 400, 500, 600, 700, 800, 900, or about 1000. In some embodiments, the number of solar cells used on a UAV can be 1,000, 2,000, 3,000, 4,000, 5,000, 6,000, 7,000, 8,000, or about 9,000. In some embodiments, the number of solar sheets used on a UAV can be more than 10,000. In some embodiments, the number of solar sheets used on a HALE UAV falls in a range of 100 to 1,000 solar sheets, 100 to 1,500 solar sheets, or 1,000 to 10,000 solar sheets.

In the embodiment depicted in FIGS. 2A and 2B, the solar cells are positioned close to a leading edge 12a of the wing with areas near the trailing edge 12b of the wing not covered by solar cells. In this particular embodiment, the center space near the trailing edge of the wing was left uncovered to avoid blocking reception of an internal antenna of the UAV. In other embodiments, additional solar cells could be mounted in the areas near the trailing edge 12b of the wing (e.g., by incorporating more solar cells into sheets 30 and 36 or by adding additional solar sheets) to increase the amount of solar power generated and thereby further enhance UAV endurance.

In the embodiments of FIGS. 2A and 2B, the solar sheets are mounted on an upper surface of the wing 12. In some embodiments, solar cells (e.g., one or more solar sheets) are applied to other surfaces of the UAV or to other components of the UAV, including, but not limited to, one or more of: the horizontal stabilizer, the vertical stabilizer, the fuselage, and the underside of the wings. Solar cells on the sides and underside of the UAV collect light scattered from the ground as well as from the sun and sky.

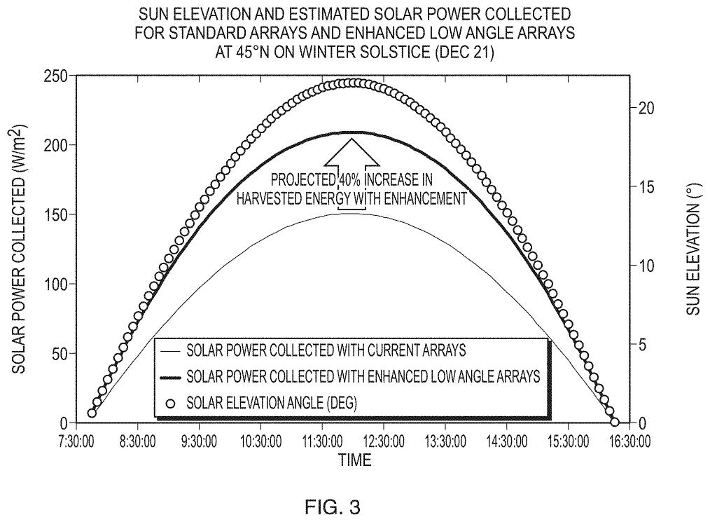

FIG. 3 is a plot illustrating the improvement in solar power collection as a function of time of day (i.e., as a function of changing sun elevation) for embodiments of devices described herein. Using conventional solar cells or sheets, HALE platforms can operate year-round at low latitudes where the sun is always at high elevations in the sky (i.e., in an equatorial zone). Improvements to the solar sheet to include prismatic structures as described herein can improve performance at lower sun angles and allow the aircraft to function more effectively in high latitude locations and during winter months when the sun does not rise high into the sky. The flexible textured coversheet 110 and other material layers can encapsulate the solar cells while reducing the reflection of light at shallow incidence angles. These materials can be applied onto a solar cell array or solar sheet (i.e., an epitaxial lift-off thin film solar sheet) for greater solar energy generation at low angles compared to the current manufactured arrays. As shown in FIG. 3, solar sheets having flexible coversheets with prismatic structures as described herein can provide at least a 40% increase in harvested energy over conventional solar sheets.

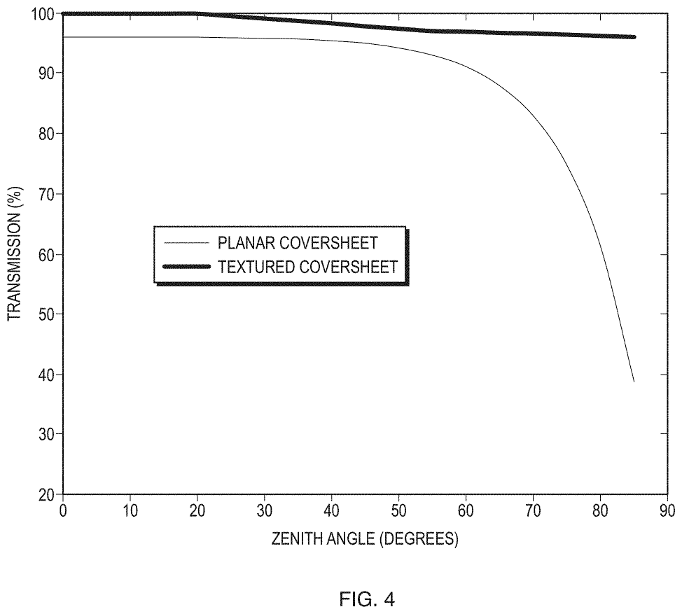

The use of a textured polymer cover sheet (e.g., an embodiment of the coversheet 112) can increase the collection and power conversion efficiencies through improved optical coupling into the solar cell by reducing the amount of reflected light. The relative efficiency benefits of texturing are most significant at large solar zenith angles. The improved optical coupling enabled by texturing is demonstrated in FIG. 4, which illustrates the transmission of unpolarized light at between 350 and 1250 nm through the top surface of planar and textured coversheets as a function of incident zenith angle. For zenith angles greater than 60°, the textured coversheet (e.g., an embodiment of the coversheet 110) as described herein can transmit substantially more light than the planar coversheet due to the reduction in Fresnel losses. This improvement in transmission at high zenith angles is particularly important for UAV performance during operation in the winter in high latitude locations. As an example, the solar zenith angle on January 1^{st} in Chicago remains between 65° and 90° throughout the day, and the energy harvested by a solar powered stratospheric UAV over the course of the day is increased by 28% through the incorporation of a textured coversheet. The off-angle performance advantages provided by texturing can enable year-round stratospheric UAV missions at high northern and southern latitudes and can substantially reduce the cost of solar powered UAVs through increases in power conversion efficiency at off-angle incident sunlight conditions.

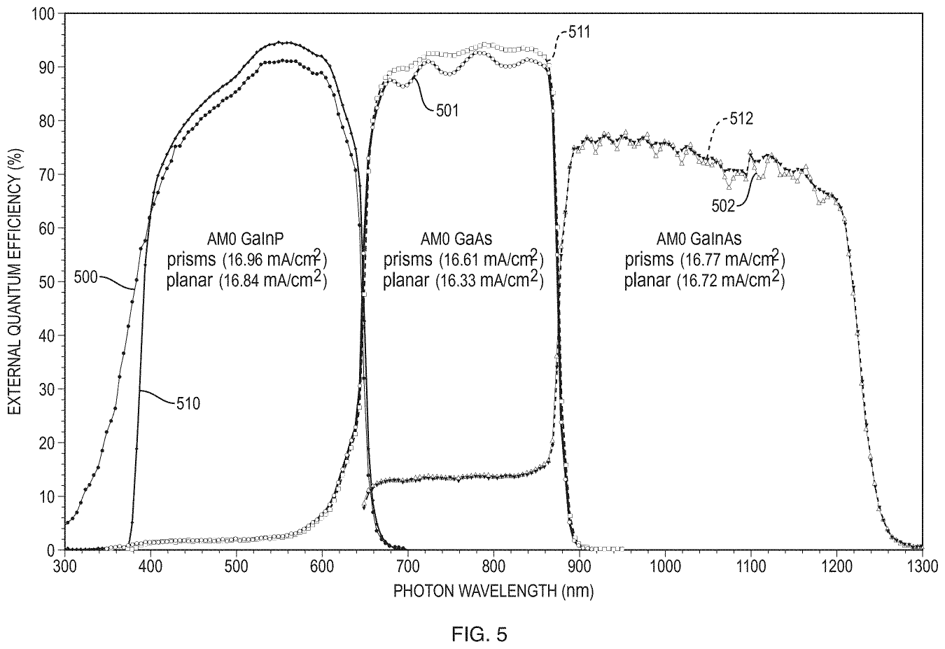

FIG. 5 is a plot illustrating the external quantum efficiencies (EQE) for each junction of a triple-junction (3J) solar cell including a conventional coversheet vs. a 3J solar cell including a coversheet as described in embodiments herein. As shown, the curves 510, 511, 512 representing EQE for junctions in the solar cell as described herein show higher EQE values than the curves 500, 501, 502 representing the EQE for junctions in the conventional solar cell. Solar cells and sheets including textured coversheets as described herein have superior EQE compared to solar cells that are otherwise identical aside from the use of a non-textured, planar coversheet. Solar sheets including the flexible coversheet with prismatic structures as described herein have superior EQE compared to identical cells with a non-textured, planar coversheet.

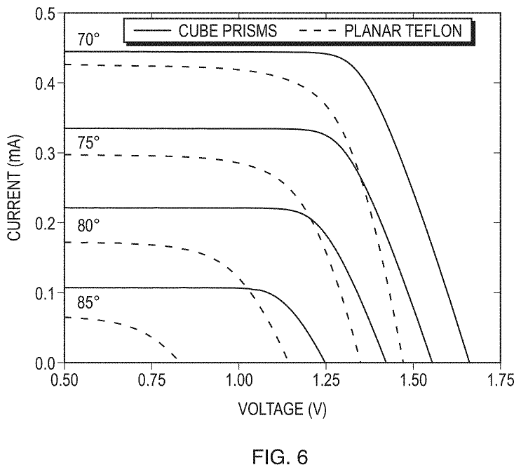

FIG. 6 is a plot illustrating the current-voltage (I-V) response as a function of solar zenith angle for a 3J solar cell including a conventional coversheet (i.e., devoid of a textured surface including prismatic structures) versus a 3J solar cell including a coversheet as described in embodiments herein (e.g., embodiments of the coversheet 110). As shown, solar cells including the flexible coversheet with prismatic structures as described herein have superior current-voltage characteristics at large zenith angles compared to otherwise identical cells that use a standard planar coversheet. In every case, the devices as described herein showed improved performance relative to conventional devices (i.e., higher current and open-circuit voltage). Greater improvements are observed at higher incident light angles.

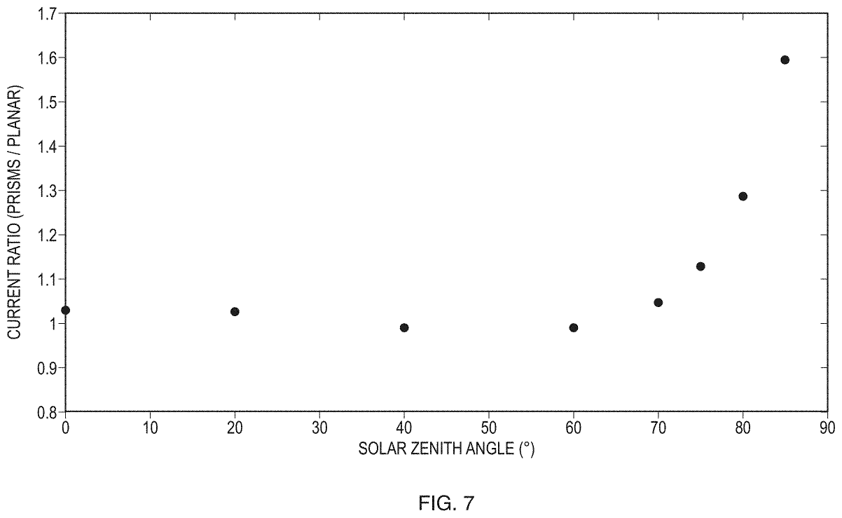

FIG. 7 is a plot illustrating the ratio of solar cell current output as a function of solar zenith angle for a 3J solar cell including a conventional coversheet vs. a 3J solar cell including a coversheet as described in embodiments herein. As shown, solar cells including the flexible coversheet with prismatic structures as described herein have superior current output at large zenith angles compared to otherwise identical cells that use a standard planar coversheet. At an angle of 85 degrees, the increase in current was approximately 60%. In some embodiments, the light collection efficiency of the solar sheet can be greater than 90% at a zenith angle of 75°.

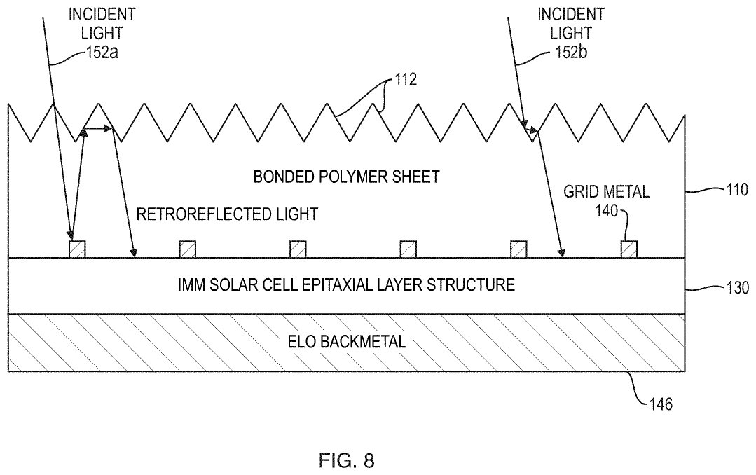

FIG. 8 illustrates the recapture and retroreflection of light in a solar cell according to various embodiments described herein. Retroflection and recapture are additional benefits provided by flexible coversheets including prismatic structures as described herein. Because of the unique texturing provided by the prismatic structures, light reflected off of the solar cell surface can be reflected or recaptured in multiple ways as shown in FIG. 8.

In conventional structures, some light that passes into the coversheet may still be lost due to reflection from the metal grid lines or reflection off of the solar cell surface itself. The active layers 130 of the solar cell are typically coated with multi-layer antireflection coating 125, which reduces but does not eliminate all reflections. In some embodiments, retroreflection may arise when incident light 152a is reflected back from grid lines or the surface of the active layers undergoes total internal reflection at the interface between the flexible coversheet and the surrounding medium (e.g., air). The light is then redirected back to the active layers 130 where there is another opportunity for absorption. The internal reflection of the light from the prismatic structure shown in FIG. 8 can include reflections from two prism facets, which can be appropriate for high index materials. In other embodiments, the internal reflection of the light includes reflections from three facets (e.g., the “corner-cube prism” effect).

Recapture may arise if incident light 152b reflects from a first prismatic structure on the top surface of the coversheet at a trajectory that causes the light to strike a second prismatic structure where the light can be directed toward the solar cell layers. This recaptured light would have otherwise been lost without the presence of the prismatic structures.

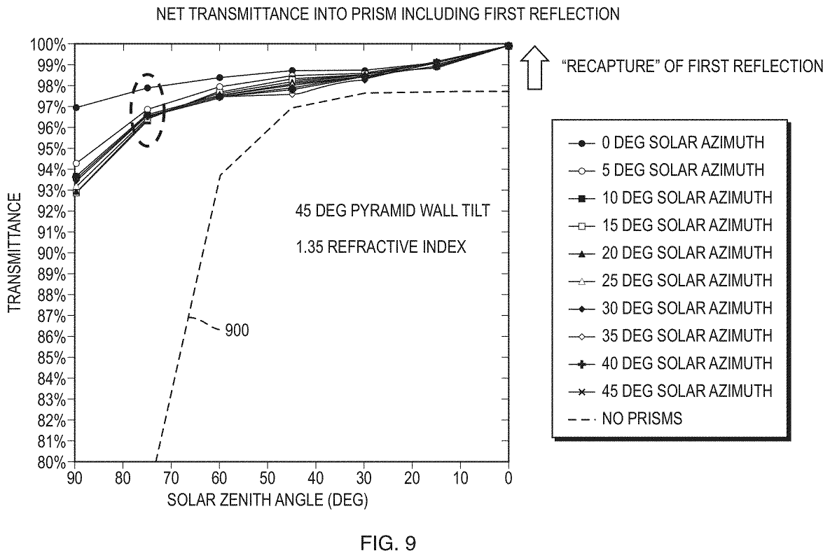

By providing additional chances to capture each photon, the overall loss is reduced and the conversion efficiency is increased. The recapture and retroreflection of photons occurs across the range of zenith angles. In some embodiments, the recapture or retroreflection of photons that can occur at nearly overhead angles (e.g., zenith angles in a range from 0° to 20°) means that the prismatic structures provide an overall improvement in conversion efficiency both when the sun is high in the sky and when the sun is close to the horizon (high zenith angle) as described above. FIG. 9 illustrates the simulated transmittance of light as a function of solar zenith angle and solar azimuthal angle for solar cell coversheets having pyramidal prismatic structures according to various embodiments described herein (e.g., embodiments of the prismatic structures 112). The simulation involved prismatic structures having a four-sided inverted prism design with a sidewall angle of 45 degrees. The plot shows the calculated transmission of light for a full range of azimuth angles from 0 to 45°. The dashed curve 900 shows the transmission for a non-textured, planar sheet. For curve 900, the transmittance drops off rapidly for high zenith angles. In comparison, the prismatic structures show very high transmission that is greater than 96% even at very steep zenith angles of 75°. At normal incidence (corresponding to 0 degrees in the plot), the prismatic structures also provide an improvement in transmission of several percent as compared to the non-textured, planar sheet. This increase is due to recapture of reflected light as described above in relation to FIG. 8. The prismatic structures therefore offer a clear performance enhancement over a wide range of incident angles from zero to 90 degrees.

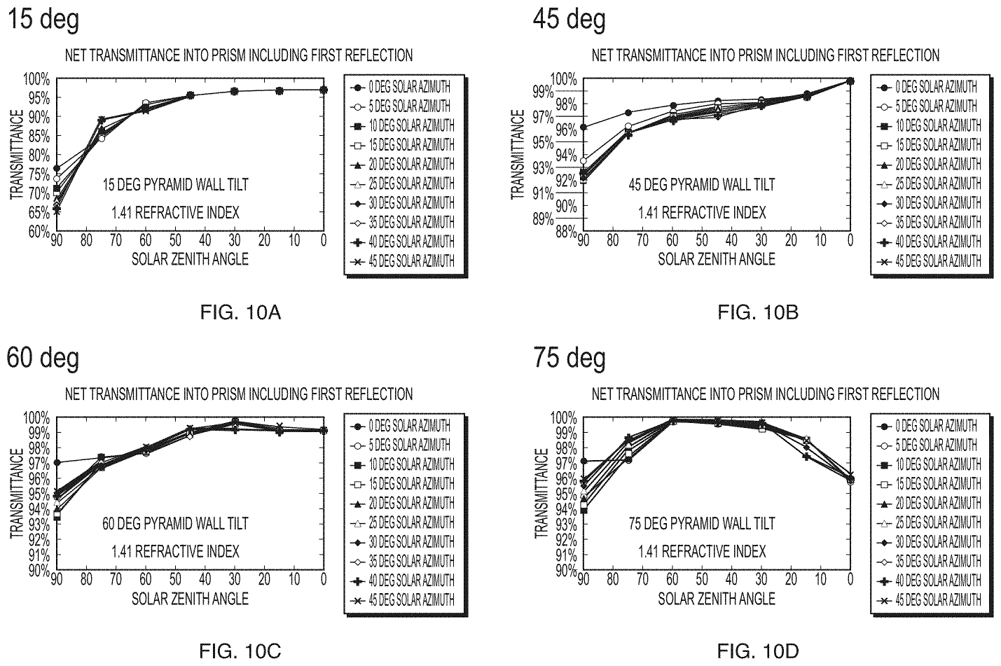

FIGS. 10A-10D show four different plots similar to that shown in FIG. 9 in which the prism sidewall angle is varied from 15 to 75 degrees. In exemplary embodiments, the sidewall angle of the prismatic structures is in a range from 45° to 60°. As the sidewall angle is increased, the performance at high zenith angles is improved relative to low zenith angles. For a sidewall angle of 75°, the transmission at normal incidence (with a 0 degree zenith angle) begins to degrade by several percent.

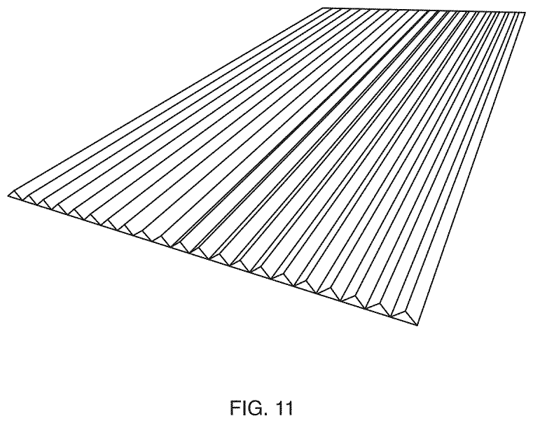

FIG. 11 illustrates a three-dimensional rendering of multiple linear prismatic structures. Linear prismatic structures may offer greater ease of manufacturability as compared to other prismatic structures in some embodiments as the “mold” used to form linear prismatic structures is relatively straightforward to machine. Additionally, the dimensions of linear prismatic structures may scale to thinner sheet materials more readily than other prismatic structures and thereby enable reduction of the overall weight of the structure. In some embodiments, linear prismatic structures may be easier to clean because their structural configuration avoids small-dimension “pockets” that can collect dust or debris.

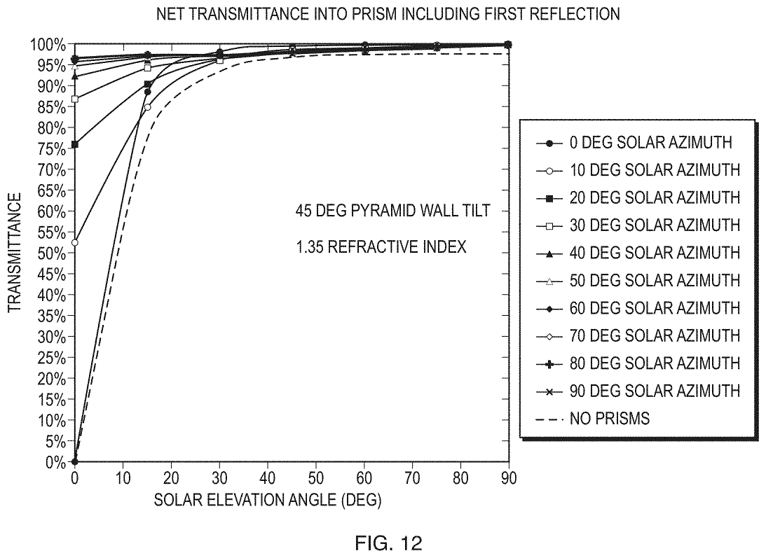

FIG. 12 illustrates the results of a ray tracing model of the angular dependence of linear prismatic structures in a solar cell coversheet wherein the sidewall angle of the linear prismatic structures is 45°. Each curve represents light arriving at a different solar azimuthal angle and is plotted as a function of solar zenith angle. As previously described, the dashed red curve represents the flat planar design with no prismatic structures. For the majority of azimuth angles, the linear prismatic structures show very high transmission of greater than 90 percent. The exception is for azimuth angles closely aligned with the prisms (i.e., between azimuth angles of approximately 0-10 degrees) for which the performance is similar to the planar design. In accordance with various embodiments, this reduced performance over a narrow range of shallow azimuthal angles is expected to have a relatively minimal impact on the total energy collection integrated over a wide range of azimuth and elevation angles. Therefore, from an optical performance perspective, the linear prismatic structures (i.e., predominantly one-dimensional structures) represent a viable alternative to multi-side or pyramidal prismatic designs (i.e., two-dimensional structures).

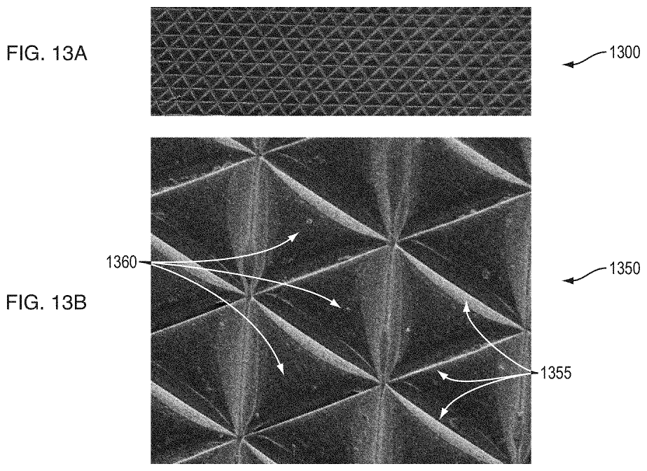

FIGS. 13A and 13B include SEM images 1300 and 1350 at different magnification factors of a polymer sheet with a textured surface (e.g., an embodiment of the polymer sheet 110) formed of fluorinated ethylene propylene (i.e., a variant of Teflon®) and including prismatic structures (e.g., an embodiment of the prismatic structures 112) according to various embodiments described herein. The polymer sheet was prepared in this example using an embossing technique. The polymer sheet can allow optical transmission well into the ultraviolet (extending to at least 350 nm), which can correspond to the spectral bandwidth of the associated solar cells in some embodiments. In some embodiments, the polymer sheet can have high optical transmission in a wavelength range from approximately 350 nm to approximately 1300 nm or in a range from approximately 300 nm to approximately 1800 nm. The polymer sheet can be laminated onto the solar cell using a silicone-based pressure-sensitive adhesive in some embodiments. For the polymer sheet depicted in FIGS. 13A and 13B, the prismatic structures are three-sided positive pyramid structures. The valleys 1355 between the pyramids are sharply defined, but the apexes 1360 of the pyramids are rounded-off rather than forming sharp peaks.

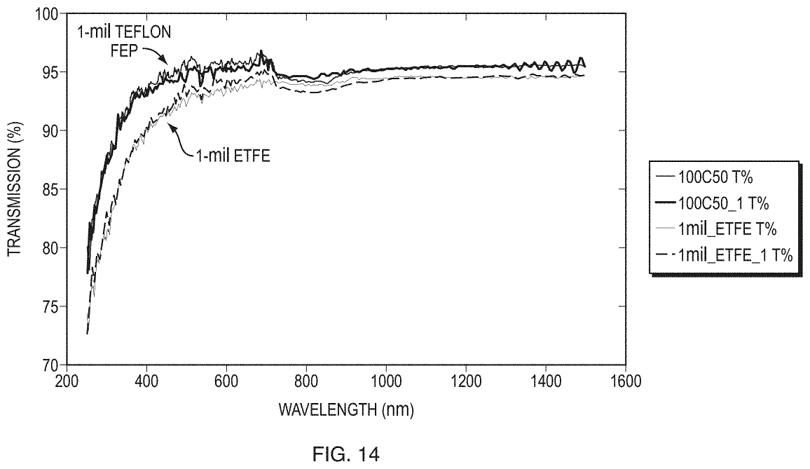

Embodiments of the flexible polymer sheet (e.g., embodiments of the polymer sheet 110) can be formed of one or more materials. The material(s) can be selected to impart particular desirable properties such as optical transmissivity at particular wavelengths or wavelength ranges, enhanced durability, or enhanced machinability in forming the prismatic structures. In some embodiments, the materials can include one or more selected from the group of fluorinated ethylene propylene (FEP), ethylene tetrafluoroethylene (ETFE), ethylene chlorotrifluoroethylene (ECTFE), and polychlorotrifluoroethylene (PCTFE). ETFE and ECTFE in particular are fluorinated polymers with optical transmission over a wide range of wavelengths as well as high durability and resistance to degradation under long-term ultraviolet light exposure. FIG. 14 shows the measured optical transmission as a function of wavelength for 1 mil-thick sheets of both Teflon FEP and ETFE. At shorter wavelengths (below 600 nm), the ETFE has moderately lower transmission than Teflon FEP, but this difference is expected to be acceptable for many applications. Increased absorption at short wavelengths may be a trade-off for other features such as durability in thicker coversheets (i.e., 3-4 mil). In some embodiments, the transmissivity of the polymer sheet 110 can be greater than 85% for wavelengths of light in the range from 400 to 1500 nanometers.

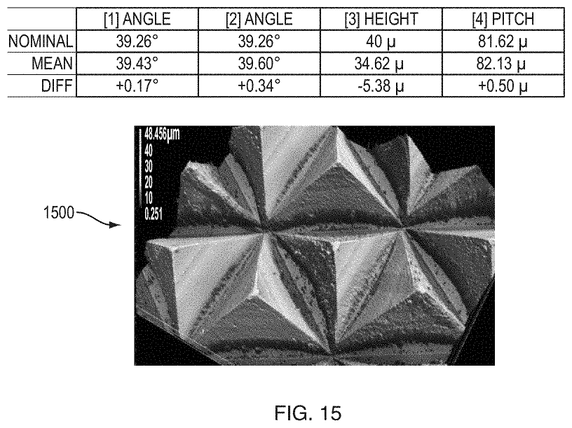

FIG. 15 illustrates a scanning laser confocal microscope image 1500 and related table of values for an ethylene chlorotrifluoroethylene (ECTFE) coversheet including a plurality of prismatic structures produced by embossing according to various embodiments described herein. The prismatic structures are three-sided positive pyramid structures. After optimization of embossing process parameters, high-quality prismatic patterns were transferred into the ECTFE material and ETFE (not shown). A total of twenty-five measurements were carried out across five different samples to generate the data table shown, which includes measured geometric parameters for the pyramids (two different angles, height and pitch). The pyramids were well defined and uniform. Similar results were obtained for ETFE materials.

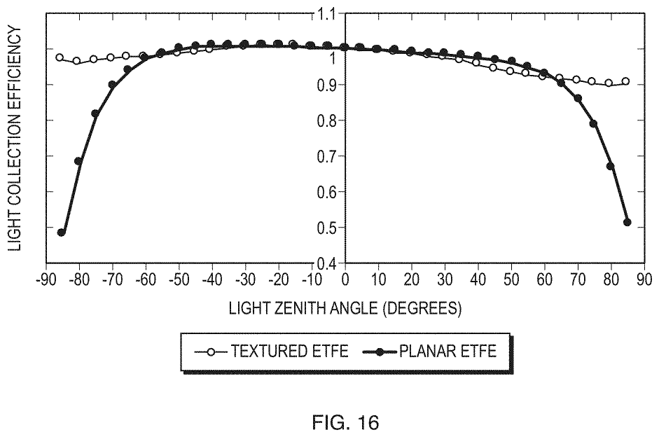

FIG. 16 illustrates comparative light collection efficiency as a function of incident light angle for a conventional solar cell compared to a solar cell including pyramidal prismatic structures according to various embodiments described herein. The textured ETFE coversheet shows improved performance at high zenith angles above 50 degrees versus untextured sheets and exceeds 90% transmission from −85 to +85 degrees. Identical results were obtained for textured ECTFE top sheets. This result clearly establishes the feasibility of using textured fluoropolymer materials for improving the angular performance of solar arrays.

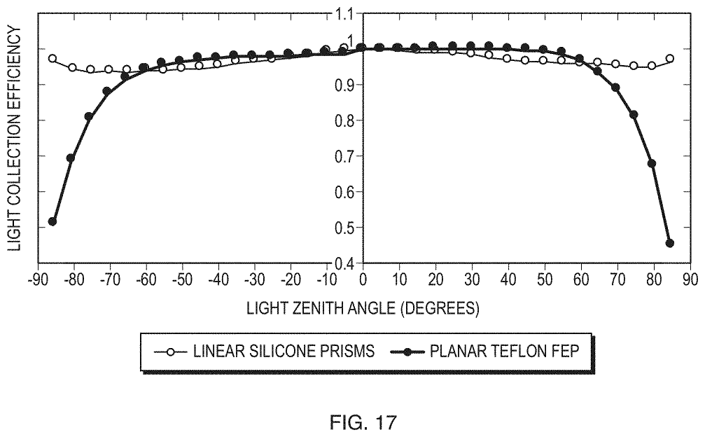

FIG. 17 illustrates a similar comparison to that shown in FIG. 16 except that linear prismatic structures are formed on the coversheet. The prismatic structures in this embodiment are formed of silicone polymer. An acrylic linear prism “master” was procured and used to cast the linear prism shape into a silicone sheet, which then cures with the desired shape. Similar to Teflon FEP, ETFE and ECTFE, the silicone has high optical transmission. As seen in FIG. 17, the linear prismatic structures provide high transmission across the full angular range. The measurement was acquired with the prisms perpendicular to the plane of rotation.

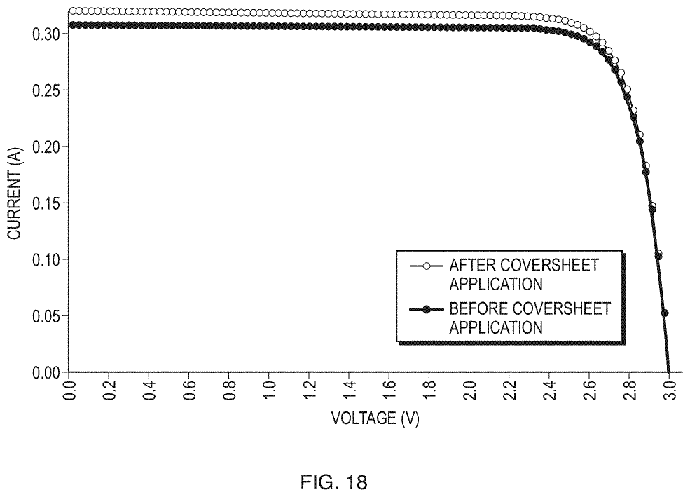

Modeling has shown that the prismatic structures can also improve solar array performance by several percent at normal incidence by “recapturing” the small percentage of light that is reflected. This occurs when the light is reflected off one prism facet and is transmitted into an adjacent prism or when light reflects from the solar cell/top electrode surface but is recaptured upon total internal reflection from the prism. FIG. 18 shows solar cell I-V characteristics that are measured for a single solar cell before and after lamination with the linear prism cover sheet. This measurement was carried out at one-sun AM0 using a carefully calibrated 3-zone solar simulator. The measurement shows a substantial current boost of 4% after lamination. A typical planar Teflon FEP cover sheet does not provide any improvement in current after lamination. This represents a very important benefit of the textured cover sheets, in addition to their improved high-angle performance.

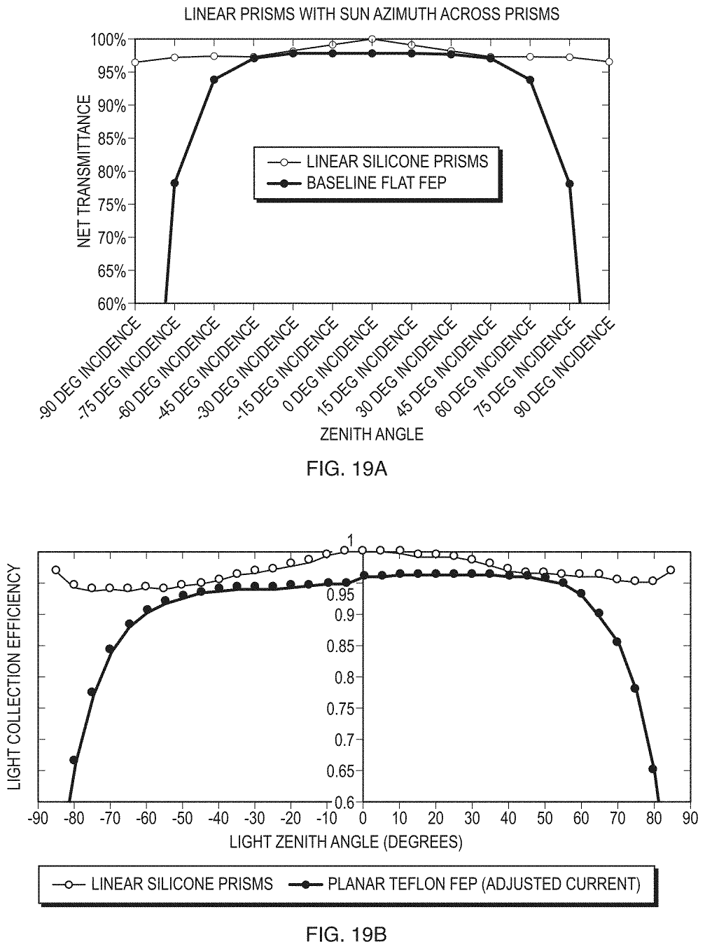

FIGS. 19A and 19B show a direct comparison in modeled and measured data, respectively, for the linear prism design with the planar Teflon FEP baseline shown for reference in each case. The relative currents for the measured linear prism and planar Teflon FEP samples have been adjusted by the ratio measured at normal incidence in FIG. 18 (about 96%). The modeled and measured data can be seen to be in agreement.

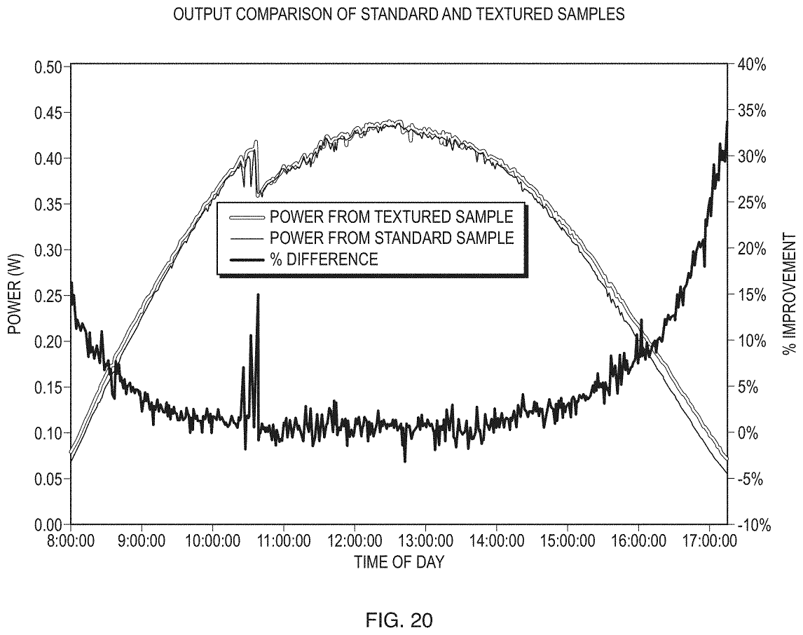

FIG. 20 shows the data summary for outdoor measurements comparing the textured sample vs. the standard, non-textured, planar sample. Both samples were kept level to the ground for the duration of the day. All the measurements started at 8:00 AM and continued to about 5:20 PM. Both solar cells show a sine wave-like increase and decrease in output power over the course of the day where the peak occurs around solar noon which was about 12:50 PM local time as would be expected. A closer inspection of the differences between the textured and planar sample shows that the output power is higher for the textured sample particularly towards sunrise and sunset when the sun elevation is quite low. This confirms the calibrated, indoor measurements showing greater performance compared to planar samples at shallower incident angles. It is noted that around 10:30 AM there was an abrupt change in the measured values. This was due to positioning and orientation of both samples being slightly moved at that moment.

The plurality of solar cells may be single-junction solar cells, multi-junction solar cells (e.g., dual-junction solar cells, triple junction solar cells) or any combination of single-junction solar cells and multi-junction solar cells. Although triple junction solar cells generally have a higher efficiency than that of single junction or dual-junction solar cells, triple junction solar cells are generally more complicated to produce and may have a narrower wavelength range for high efficiency performance. The efficiency of the dual-junction and single-junction cells is less sensitive to the spectrum of the incident light than that of a triple-junction cell, so more energy may be obtained from dual-junction or single-junction cells when the cells are exposed to scattered light, rather than to direct sunlight. Accordingly, in some embodiments it may be desirable to use dual-junction or single-junction cells on the underside of the wings or the fuselage where the ratio of scattered light to direct sunlight is greater than for a top side of the wings.

The solar cells, and any solar sheets into which the solar cells are incorporated, must be flexible to conform to an underlying curved aerodynamic shape of a surface of UAV or of a UAV component onto which they will be mounted or into which they will be incorporated. Solar cells for a small UAV may need to be more flexible than solar cells for a large UAV due to the higher curvatures present in surfaces of small UAVs. Further, flexible solar cells are more durable than similar non-flexible or less flexible (i.e., more brittle) solar cells during installation, and during use.

As noted above, the solar cells and the solar sheets that include the solar cells should have a total mass that is relatively small compared to the mass of the UAV and should have a relatively low mass per unit area.

Because additional mass tends to increase the power required to operate a UAV, the power supplied by the solar cells must more than compensate for the increase in the UAV mass due to the presence of the solar cells or solar sheets into which the solar cells are incorporated to increase endurance of a UAV. Thus, only solar cells having sufficient specific power (power per unit mass) would increase the endurance of a UAV.

For UAVs that is designed to incorporated solar cells and solar sheets using higher specific power solar cells or higher specific power solar sheets can increase the payload capacity of the UAV by increasing the available power for a given mass of solar cells or solar sheets incorporated into the UAV. Using higher specific power solar cells or higher specific power sheet may reduce the mass of solar cells or solar sheets incorporated into the UAV to generate a given power.

For a given solar cell, the efficiency for one spectrum of light is generally different than the efficiency for another spectrum of light. Parameters which depend on the efficiency of the solar cell can be specified for different types of illumination. For example, the specific power of solar cells or solar sheets can be specified under air mass coefficient 1.5 (AM1.5) light which is typically used to characterize low altitude or terrestrial based solar cells. The specific power of solar cells or solar sheets can alternatively or additionally be specified under air mass coefficient 0 (AM0) light, which corresponds to high altitude conditions or light conditions above the atmosphere.

Various types of commercially available solar cells as well as ELO IMM triple-junction ((Al)InGaP/GaAs/InGaAs) solar cells and IMM cells with more than three junctions made by MicroLink Devices, Inc. can be used in conjunction with embodiments of the present disclosure. In some embodiments, aluminum can be included in the first junction (e.g., AlInGaP/GaAs/InGaAs) and in some embodiments aluminum was not included in the first junction (e.g., InGaP/GaAs/InGaAs) depending on the application or use. For example, the triple-junction InGaP/GaAs/InGaAs solar cell performs well under AM1.5. But, under AM0, AlInGaP/GaAs/InGaAs can be used because the Al can help the first junction to be better tuned to the high UV content of AM0 as compared to AM1.5.

The commercially available solar cells include single-junction polycrystalline silicon solar cells, single-junction single crystal silicon solar cells, triple junction gallium arsenide solar cells on germanium, triple-junction solar cells on germanium, and single-junction copper-indium-gallium-selenide (CIGS) solar cells. Both polycrystalline silicon solar cells and single crystal silicon solar cells are rigid solar cells, (i.e., not flexible solar cells). CIGS solar cells are grown on glass, polymers and metal sheets. CIGS solar cells are flexible, but they typically have a lower efficiency compared to silicon or GaAs-based solar cells. The GaAs solar cells, which are grown on the Ge substrate, are both rigid and fragile; however, due to their high efficiency, they are often used for space solar arrays.

In some embodiments not including textured coversheets, a specific power of the plurality of solar cells is at least a threshold value (e.g., at least 1000 W/kg, at least 1500 W/kg, at least 2000 W/kg, at least 2500 W/kg, for AM1.5). The threshold value may alternatively, or additionally be specified with respect to AM0 (e.g., at least 1220 W/kg, at least 1870 W/kg, at least 2520 W/kg, or at least 3150 W/kg, under AM0). In some embodiments, the specific power of the solar cells falls within a specified range (e.g., 1000-4500 W/kg, 1500-4500 W/kg, 2000-4500 W/kg, 2500-4500 W/kg, or 1500-6000 W/kg under AM1.5). The range may alternatively, or additionally, be specified with respect to AM0 light (e.g., 1220-5680 W/kg, 1870-5680 W/kg, 2520-5680 W/kg, 3150-5680 W/kg, or at least 1870-7000 W/kg, under AM0).

The specific power of a solar cell depends on the efficiency of the solar cell (electrical energy produced divided by solar energy absorbed for a unit area of the solar cell) and the mass per unit area of the solar cell (i.e., the areal mass). Thus, a solar cell with a relatively high specific power has a relatively high efficiency and/or a relatively low areal mass. Solar cells free of a substrate (e.g., solar cells produced using epitaxial lift off (ELO)) may be particularly well suited for use on a UAV because they have a reduced mass per unit area and greater flexibility as compared to solar cells attached to an underlying substrate.

In general, if the materials of a solar cell remain the same, decreasing the thickness of the solar cell increases the flexibility of the solar cell. As noted above, increased flexibility allows the solar cell to conform to an aerodynamic shape of a UAV surface or of the surface of a UAV component and increases the durability of the solar cell. In some embodiments, the solar cell (including components thereof such as the flexible polymer sheet) can flex in two dimensions to a bend radius down to 1 centimeter. In some embodiments, each solar cell may have a thickness of less than a specified thickness (e.g., less than 40 μm, less than 25 μm, less than 13 μm, or less than 5 μm). In some embodiments, each solar cell may have a thickness that falls in a specified range (e.g., 2-40 μm, 2-30 μm, 2-15 μm).

The areal mass of a solar cell is independent of the light spectrum used for power generation (i.e., AM1.5 or AM0). In some embodiments, the areal mass of a solar cell may have a value that falls in a specified range (e.g., 70-280 g/m², 165-250 g/m², 95-165 g/m², 70-95 g/m²). The areal mass of the solar cell can be reduced by reducing the mass of one or more components of the of solar cell without reducing the area of the solar cell. For example, for solar cells that include a backing layer, such as ELO IMM solar cells including a backing layer, reducing the thickness of the backing layer of the solar cell can reduce the areal mass of the solar cell. In some embodiments, the solar cell includes a metal backing layer. In some embodiments, the metal backing layer may have a thickness of less than a specified thickness (e.g., less than 30 μm, less than 15 μm, or less than 5 μm). In some embodiments, the backing layer can include metal and polymer.

Areal power of a solar cell is dependent on the efficiency of the solar cell. The areal power of a solar cell is greater under AM0 than under AM1.5. This is due to the fact that AM0 light inherently has more power to begin with because, unlike the AM1.5 light, the AM0 light has not been filtered by atmospheric conditions. In some embodiments, the efficiency of the solar cells under AM0 varies by 2.5% from efficiency of the solar cells under AM1.5. For example, if the solar cell has 25% efficiency under AM0, it has about 27.5% efficiency under AM1.5. In some embodiments, the solar cell has 29% efficiency under AM1.5 which results in an areal power of 290 W/m² under AM1.5, and the solar has 26.5% efficiency under AM0 which results in an areal power of 360 W/m² under AM0. In another embodiment, the efficiency of the solar cell can increase to 30% under AM0 resulting in an areal power of 410 W/m² under AM0 and as a result, the efficiency of the solar cell can increase to 32.5% under AM1.5 resulting in an areal power of 325 W/m² under AM1.5.

In some embodiments, the areal power of the solar cell may be in the range of 260-360 W/m² under AM1.5. In some embodiments, the areal power of the solar cell may be in the range of 325-450 W/m² under AM0.

As noted above, at least some solar cells (e.g., embodiments of solar cells 130) may be incorporated into a flexible solar sheet (e.g., embodiments of solar sheets 100). For example, in some embodiments, lightweight solar cells (or strings of solar cells) are disposed under a polymer film or between polymer films to form flexible solar sheets to aid in easier handling and installation, and to provide greater protection of the solar cells. The flexible solar sheets conform to curved aerodynamic surfaces. In some embodiments the flexible solar sheets provide robust waterproof packaging. The flexible solar sheets may be applied to or incorporated into a surface of a UAV or of a component of a UAV.

The areal mass of a solar sheet includes the encapsulating materials that form the solar sheet ready to be installed on a UAV. As noted above, decreasing the mass of solar sheet increases the specific power of the solar sheet. The main factor for reducing the areal mass of the solar sheet is the reduction in thickness of the encapsulating materials by substituting lighter materials and eliminating redundant materials. In some embodiments, the areal mass of the solar sheet may have a value that falls in a specified range (e.g., 120-570 g/m², 120-300 g/m², or 120-160 g/m²).

The areal power of a solar sheet is dependent on the efficiency of the solar cells in the solar sheet as well as how tightly the solar cells are packed together in an array in a solar sheet. One way to increase the areal power of the solar sheet is by reducing or minimizing the spacing or the lateral gaps between adjacent solar cells in the solar sheet. In one embodiment, the solar cells were spaced 2 mm or more from each other resulting in a sizable amount of area on the solar sheet that was not active and did not contribute power to the whole solar sheet. The areal power of the solar sheet was measured to be 230 W/m² under AM1.5. In another embodiment, the solar cells were packed with less than 1 mm spacing between adjacent cells. The areal power of the solar sheet was measured to be 260 W/m² under AM1.5 and 330 W/m² under AM0.

The overall increase in mass of the UAV due to installation of a kit or due to installation of solar sheets should be small relative to the total weight of the UAV. For example, in some embodiments the installed kit or the installed solar sheets increase the weight of the UAV by less than 2%, by less than 5%, by less than 10%, by less than 15%, or by less than 20%. As noted above, this requirement may be more challenging for small UAVs than for large UAVs.

Solar cells for the kit or solar cells used with embodiments employing solar sheets may be based on any number of suitable semiconductor materials like III-V semiconductor materials (e.g., GaAs-based materials, InP-based materials, etc.) and Si-based materials. The solar cells may be single junction solar cells, multi-junction solar cells (e.g., double-junction, triple-junction), or a combination of single junction and multi-junction solar cells. In general, higher efficiencies can be obtained with multi-junction solar cells than with single junction solar cells, however, multi-junction solar cells are more complicated to make and can be more expensive. Examples of solar cells having relatively high efficiencies include triple junction inverted metamorphic (IMM) solar cells, which may be produced using ELO or using methods that do not employ ELO. As a specific example, triple junction IMM solar cells with an (Al)InGaP/GaAs/InGaAs grown inverted on GaAs by the inventors demonstrated efficiencies of greater than 29% under AM0.

Further information regarding III-V semiconductor solar cells produced by ELO (e.g., single junction, multi-junction and IMM solar cells), and how to manufacture III-V semiconductor ELO solar cells may be found in U.S. Pat. No. 7,994,419 to Pan et al. issued Aug. 9, 2011, which is incorporated by reference herein in its entirety. Further information regarding InP-based solar cells produced by ELO (single junction, multi-junction and IMM) and how to manufacture InP-based ELO solar cells may be found in U.S. patent application Ser. No. 13/631,533, filed Sep. 28, 2012, which is incorporated by reference herein in its entirety.

For embodiments that include a kit, the kit includes a power conditioning system configured to operate the plurality of solar cells within a desired power range and configured to provide a specified voltage to an electrical system of the UAV. FIG. 21 is a block diagram of a power conditioning circuit 50 included in the power conditioning system in accordance with some embodiments. The power conditioning circuit 50 includes a maximum power point tracker (MPPT) 52 connected with the solar cells. The MPPT 52 is configured to operate the solar cells within a desired power range. Any type of suitable MPPT component or circuit may be employed. The power conditioning circuit also includes a voltage converter 54 that converts voltage from the MPPT into a voltage compatible with the electrical system of the UAV. Any suitable voltage conversion component or circuit may be employed (e.g., a buck voltage converter (DC to DC voltage reduction), a boost voltage converter (DC to DC voltage increase)). In this embodiment, the voltage converter 54 is connected to an electrical system of the UAV through a switch (switch A 62).

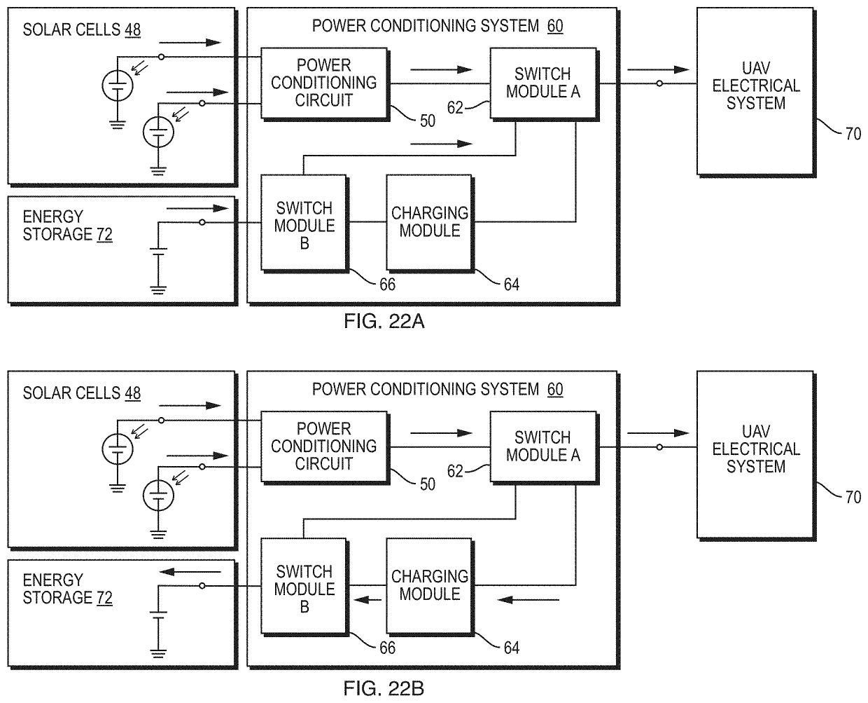

In some embodiments, the power conditioning system may also be configured to charge an energy storage device (e.g., a battery, fuel cell) of the UAV. FIGS. 22A and 22B are block diagrams representing a power conditioning system 60 configured to charge an energy storage device of the UAV in accordance with some embodiments. Power conditioning system 60 includes the power conditioning circuit 50 and switch module A 62, which connects with the UAV electrical system 70. As shown, power conditioning system 60 may also include a charging module 64 and a switch module B 66 that connect with an energy storage element 72 (e.g., a battery, fuel cell) of the UAV.

In FIG. 22A, the system is operating in a first mode in which the solar cells 48 supply just a portion of the power being used by the UAV electrical system 70. In this mode, through switch module B, the energy storage device 72 (e.g., battery, fuel cell) supplements the power supplied by the solar cells for the UAV's electrical system 70. As indicated by arrows, the charging module 64 is bypassed in this mode. In FIG. 22B, the system is operating in a second mode in which the power supplied by the solar cells 48 exceeds the power being used by the UAV electrical system 70 and the excess generated power is directed through the charging module 54 and switch module B 66 to charge the energy storage 72 (e.g., battery, fuel cell). A third mode of operation in which the power supplied by the solar cells exactly matches the power used by the electrical system is not depicted because, generally speaking, the third mode only occurs when shifting from the first mode to the second mode and vice-versa). In some embodiments, a UAV incorporating a secondary solar power system could be charged with exposure to sunlight before flight as well as during flight.

Electrical connections (e.g., power bus lines, wiring harness) connecting the solar cells, the power conditioning system, the electrical system of the UAV and the energy storage device (e.g., battery, fuel cell) of the UAV may be integrated into one or more components of the UAV (e.g., the wings or the fuselage).

Some embodiments include a solar sheet configured for installation on a component of a UAV. The solar cell may be included in a kit with a power conditioning system or may be provided without a power conditioning system. FIG. 23A schematically depicts a side cross-sectional view of a solar sheet 90 for installation on a component of a UAV in accordance with an embodiment. FIG. 23B is a detail view of FIG. 23A. The solar sheet 90 includes a plurality of solar cells 94 each having a top surface 93 and a bottom surface 91. The solar sheet 90 can include any form of the plurality of prismatic structures as described herein. Solely for illustrative purposes, the cross-section of solar sheet 90 is depicted with three solar cells. In some embodiments, the solar sheet 90 may have more than three columns or more than three rows of solar cells. In some embodiments, the solar sheet may have less than three columns or less than three rows of solar cells. In FIGS. 23A and 23B, interconnects between the solar cells are not shown for clarity. In some embodiments, each of the solar cells has a specific power in a range of 1500-4500 W/kg under AM1.5 or a specific power in a range of 1870-5680 W/kg under AM0. In some embodiments, each of the solar cells has a specific power in a range of 2000-4500 W/kg under AM1.5 or a specific power in a range of 2520-5680 W/kg under AM0. In some embodiments, each of the solar cells has a specific power in a range of 2500-4500 W/kg under AM1.5 or a specific power in a range of 3150-5680 W/kg under AM0.

The solar sheet 90 also includes a polymer layer 98 to which the plurality of solar cells 94 are attached. The polymer layer 98 can be planar (as depicted in FIG. 23B) or can include prismatic structures in accordance with embodiments described above. As depicted the polymer layer 98 is attached to the top surface 93 of the solar cells and may be described as a polymer top sheet. In some embodiments, the polymer layer 98 includes polytetrafluoroethylene, e.g., TEFLON from DuPont. In some embodiments, the thickness of the polymer layer 98 is in a range of 15 microns to 30 microns.

In some embodiments the solar sheet 90 includes a first adhesive layer 92. In some embodiments, the first adhesive layer 92 is configured to attach the solar sheet 90 to a component of a UAV. In some embodiments, the first adhesive layer 92 is in contact with a bottom surface 92 of each solar cell. The adhesive can be any suitable adhesive (e.g., NT 1001 pressure sensitive adhesive (PSA) from Forza Power Technologies). In some embodiments, the thickness of the first adhesive layer 92 is in a range of 8 microns to 15 microns. In some embodiments, the thickness of the first adhesive layer is in a range of 8 microns to 25 microns. In some embodiments, the bottom surface 91 of each of the solar cells 94 is in contact with the first adhesive layer 92.

In some embodiments the solar sheet 90 includes a second adhesive layer 96 that attaches the plurality of solar cells 94 to the polymer top sheet 98. In some embodiments, the second adhesive layer 96 is in contact with the top surface 93 of each of the plurality of solar cells 94. The second adhesive layer 96 can be any suitable adhesive (e.g. a PSA such as NT 1001). In some embodiments, the thickness of the second adhesive layer 92 is in a range of 8 microns to 15 microns. In some embodiments, the thickness of the second adhesive layer is in a range of 8 microns to 25 microns.

Although solar sheet 90 depicted in FIG. 23A and FIG. 23B does not include a bottom polymer layer, in some other embodiments, the solar sheet includes a bottom polymer layer, which may be described at a polymer bottom sheet, underlying the first adhesive layer. In such embodiments, the first adhesive layer does attach the bottom polymer layer to the other elements of the solar sheet, but is not configured to attach the solar sheet to an underlying surface of a UAV. In some embodiments, a bottom polymer layer includes polyvinyl fluoride (PVF) e.g., a TEDLAR PVF film from DuPont.

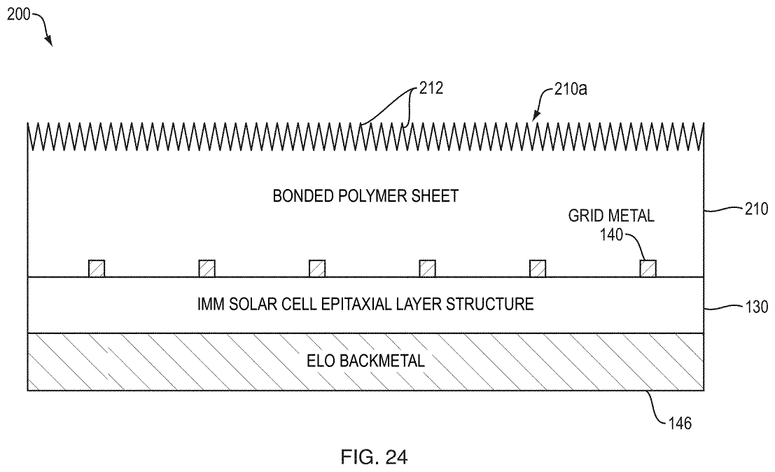

FIG. 24 illustrates a cross-sectional schematic view of a thin-film solar sheet 200 with enhanced light collection efficiency in accordance with various embodiments described herein. The solar sheet 200 includes a flexible coversheet 210 including nanostructures 212 formed in a top surface 210a thereof. The solar sheet 200 can include a layer similar to the embodiment described above with respect to FIG. 1A including an anti-reflection coating, one or more thin film solar cells 130, one or more front metal electrodes 140, and one or more back metal electrodes 146.

The nanostructures 212 formed in the top surface 210a of the coversheet 210 differs from the prismatic structures 112 described previously by having a significantly smaller characteristic dimension. The nanostructures can take the form of “moth eye” texturing. The moth eye texturing can have antireflective properties in some embodiments. The nanostructures 212 can have a characteristic dimension (e.g., period) shorter than the wavelengths of incident radiation. As a result, the nanostructures 212 can reduce Fresnel reflective losses. In some embodiments, the characteristic dimension can be below 500 micrometers. In some embodiments, the characteristic dimension can be less than the wavelength of visible light. In some embodiments, the nanostructures 212 can create a graded effective index of refraction in the flexible sheet 210 between the surrounding medium (e.g., air or vacuum) and the one or more thin-film solar cells 130. The index gradation reduces the Fresnel losses by minimizing the discontinuity in refractive index that leads to reflections.

The use of nanostructures 212 can enable reduction in thickness of the flexible coversheet 210, which thus results in reduced weight and increased specific power. In some embodiments, prismatic structures 112 as described in relation to FIG. 1A, for example, can more readily be produced at low cost due to the relatively large feature size as compared to nanostructures 212. The thickness of the flexible coversheet 210 is directly related to the size of the prismatic structures, i.e., pyramidal structures that are tens or hundreds of micrometers tall require coversheet thicknesses of a similar order. Conversely, nanostructures 212 can be more challenging to manufacture but can be realized within a relatively small thickness of coversheet 210, which can translate to lower weight and higher specific power. In accordance with various embodiments, a thickness of the flexible coversheet 210 can be in a range from approximately 1 micrometer to approximately 10 micrometers, or in a range from 1 micrometer to approximately 100 micrometers, or in a range from approximately 5 micrometers to approximately 30 micrometers. For space-based applications, the thickness of the flexible coversheet 210 can be, as a non-limiting example, in a range from 150 to 350 micrometers. FIG. 24 illustrates nanostructures 212 formed in the flexible coversheet 210 in the form of a bonded polymer sheet in accordance with some embodiments. Nanostructures 212 can be formed in sheets having a range of materials including glass.

For embodiments not including textured coversheets, each of the solar cells in the solar sheet has a specific power of at least a specified value (e.g., at least 1000 W/kg, at least 1500 W/kg, at least 2000 W/kg, at least 2500 W/kg, under AM1.5). The specific power of the solar cells in the solar sheet may additionally or alternatively be described in terms of AM0 light (e.g., at least 1270 W/kg, at least 1870 W/kg, at least 2520 W/kg, at least 3150 W/kg, under AM0). In some embodiments, each of the solar cells has a specific power falling within a specified range (e.g., 1000-4500 W/kg, 1500-4500 W/kg, 2000-4500 W/kg, 2500-4500 W/kg, 1500-6000 W/kg, under AM1.5). The specific power of the solar cells in the solar sheet may additionally or alternatively be described in terms of AM0 (e.g., 1270-5680 W/kg, 1870-5680 W/kg, 2520-5680 W/kg, 3150-5680 W/kg, 1870-7000 W/kg, under AM0). Textured coversheets can improve specific power numbers for solar sheets over those ranges given above for non-textured solar sheets.

In some embodiments not including textured coversheets, the solar sheet has a specific power of at least a specified value (e.g., at least 400 W/kg, at least 800 W/kg, at least 1000 W/kg, under AM1.5). In some embodiments the solar sheet has a specific power falling with within a specified range (e.g., 400-2350 W/kg, 800-2350 W/kg, 1000-2350 W/kg, 1020-3000 W/kg, under AM1.5). The specific power of the solar sheets may additionally or alternatively be described in terms of AM0 (e.g., at least 510 W/kg, at least 1020 W/kg, at least 1270 W/kg or in a range of 10-3000 W/kg, 1020-3000 W/kg, 1270-3000 W/kg, 1020-4000 W/kg, under AM0).

As noted above, the areal mass of the solar sheet includes the encapsulating materials that form the solar sheet ready to be installed on a UAV. Decreasing the mass of solar sheet, increases the specific power of solar sheet. In some embodiments, the areal mass of the solar sheet may have a value that falls in a specified range (e.g., 70-280 g/m², 120-570 g/m², 120-300 g/m²). The areal power of a solar sheet is dependent on the efficiency of the solar cells as well as how tightly the solar cells are packed together in an array. In some embodiments, the areal power of the solar sheet may have a value that falls in a specific range (e.g., 260-330 W/m², 200-330 W/m² under AM1.5 or 325-450 W/m², 260-410 W/m² under AM0).

In some embodiments, the solar sheet is configured to be attached to a wing of a UAV. In some embodiments, the solar sheet is a flexible solar sheet. In some embodiments the plurality of solar cells includes solar cells produced using an epitaxial lift-off process.

In some embodiments, each of the plurality of solar cells includes a backing layer. The backing layer can be formed of metal in some embodiments. In other embodiments, the backing layer can be formed of a polymer or a combination of metal and polymer. In some embodiments, the thickness of the metal backing layer is less than 30 μm, less than 15 μm, or less than 5 μm. In some embodiments, the metal backing layer has a thickness in a range of 2 to 30 microns. In some embodiments, the metal backing layer has a thickness in a range of 2 to 15 microns.

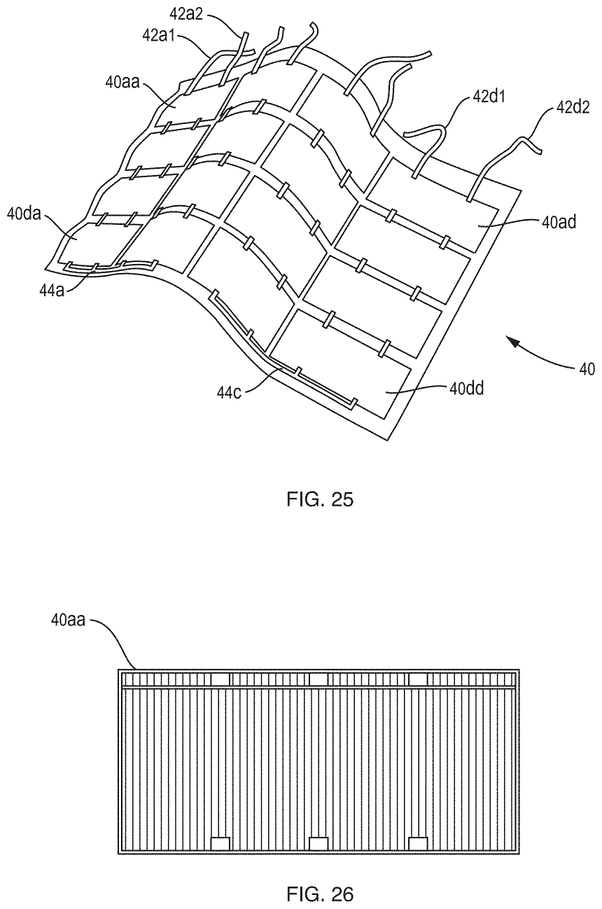

FIG. 25 illustrates the flexibility of a solar sheet 40, in accordance with an embodiment. FIG. 26 illustrates a plan view of a single solar cell 40aa. The flexible solar sheet may also include electrical components such as electrical interconnections between solar cells or electrical leads. As shown in FIG. 25, within a solar sheet 40 multiple solar cells may be electrically connected in columns and/or rows (e.g., cells 40aa-40da are connected in a solar cell string, cells 40ad-40dd are connected in a solar cell string). As also shown in FIG. 26, a solar sheet may include components for making electrical connections to the solar sheet (e.g., leads 42a1, 42a2 associated with one column, leads 42d1, 42d2 associated with another column and ground connections 44a and 44c).

Due to added mass of polymer materials in solar sheets, a solar sheet of a plurality of solar cells has a lower specific power than the specific power of the solar cells themselves. Also, if the solar sheet has a top layer, the top layer may reduce the efficiency of the solar sheet (e.g., by absorbing or reflecting some of the incident light before it reaches the solar cell). Alternatively, the textured top sheet in accordance with some embodiments of the present disclosure can improve the efficiency of the solar sheet (e.g., by recapturing light that has reflected from the solar cell surface and redirecting this light back to the surface). In some embodiments, a solar cell has a specific power of at least a specified value (e.g., at least 800 W/kg, or at least 1000 W/kg, under AM1). Additionally or alternatively the threshold for specific power may be described in terms of AM0 light (e.g., at least 1020 W/kg, at least 1270 W/kg, under AM0). In some embodiments, a solar sheet has a specific power falling within a specified range (e.g., 800-2350 W/kg, 1000-2350 W/kg, 1000-3500 W/kg, under AM1.5). Additionally or alternatively the range for specific power may be described in terms of AM0 light (e.g., 1020-3000 W/kg, 1270-3000 W/kg, 1020-4000 W/kg, under AM0).

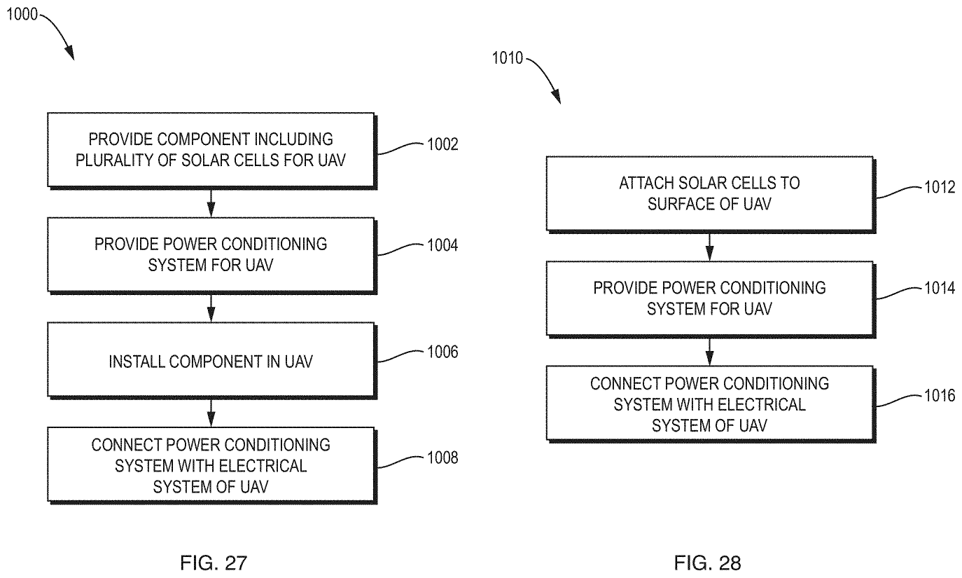

Some embodiments include methods of increasing an endurance of a battery-powered or fuel cell powered UAV. For example, in method 1000 of FIG. 27, a component that includes a plurality of solar cells is provided for a UAV (step 1002). In some embodiments the component is at least a portion of a wing for a UAV. A power conditioning system configured to operate the plurality of solar cells within a desired power range and configured to provide power in the form of a voltage compatible with an electrical system of a UAV is provided (step 1004). The component is installed in a UAV (step 1006). In some embodiments the provided component replaces a previously-produced component of a previously-produced UAV. In some embodiments, the component is installed in the UAV during manufacturing of the UAV. The power conditioning system is connected with an electrical system of the UAV (step 1008).

Method 1010 of FIG. 28 depicts another method of increasing an endurance of a battery-powered or fuel cell powered UAV. A plurality of solar cells is attached to a surface of a battery-powered or fuel cell powered UAV (step 1012). The plurality of solar cells may be attached to a surface of a wing of the UAV. In some embodiments the solar cells are attached to a surface of a previously-produced UAV. In some embodiments, the solar cells are attached during initial production of the UAV. A power conditioning system configured to operate the plurality of solar cells within a desired power range and configured to provide power in the form of a voltage compatible with an electrical system of the UAV is provided (step 1014). The power conditioning system is connected with the electrical system of the UAV (step 1016).

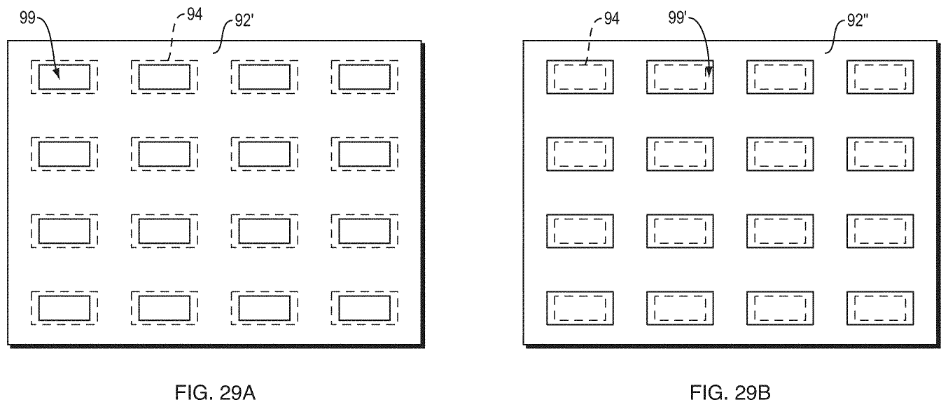

As noted above, in order to increase the specific power of a solar sheet, the areal mass of the solar sheet can be decreased. For example, in some embodiments, portions of first adhesive layer of the solar sheet include cutouts to reduce the mass of the solar sheet. FIG. 29A schematically illustrates a top view of a first adhesive layer 92′ that includes cutouts 99 with each cutout corresponding to a position of a solar cell 94. Although only the first adhesive layer is shown, for illustrative purposes the positions and areas of the corresponding solar cells in the solar sheet are indicated with dotted lines 94. In some embodiments, the area of each cutout 99 in the adhesive layer 92′ is smaller than the area of the corresponding solar cell 94, as illustrated in FIG. 29A. In some embodiments, the area of each cutout 99′ in an adhesive layer 92″ is larger than the area of the corresponding solar cell 94, as illustrated in FIG. 29B. In some embodiments, the area of each cutout in an adhesive layer is about the same as the area of the corresponding solar cell. In such embodiments, a frame or window structure for the first adhesive layer provides sufficient adhesion to secure the solar sheet to an underlying component of the UAV while achieving a significant mass reduction.

In some embodiments, the second adhesive layer includes a plurality of cutouts, each corresponding to a position of a solar cell in the solar sheet. In some embodiment, both the first adhesive layer and the second adhesive layer include a plurality of cutouts, each corresponding to a position of a solar cell in the solar sheet.

In some embodiments, the plurality of solar cells are integrated into a component of a UAV. For example, solar sheets may be produced as described above and then the solar sheets incorporated into a wing as the wing is produced using a molding process.

### Example Solar Sheet A

The inventors made and tested an example solar sheet having a planar coversheet (e.g., devoid of prismatic structures such as polymer layer 98 shown in FIG. 23B), which is referred to as example solar sheet A. The solar cells used in example solar sheet A were flexible and triple-junction AlInGaP/GaAs/InGaAs inverted metamorphic (IMM) solar cells made using an ELO process. Specifically, the cell included an AlInGaP top cell, a GaAs middle cell and a InGaAs bottom cell overlaying a metal backing layer. As noted above, additional details regarding manufacturing of a triple-junction IMM solar cell, may be found in U.S. Pat. No. 7,994,419, which is incorporated by reference herein in its entirety. The metal backing layer of each solar cell was about 25 microns thick. Example solar sheet A had an areal mass of 543 g/m². The areal power of example solar sheet A was measured to be 230 W/m² under AM1.5 and 290 W/m² under AM0. The specific power of example solar sheet A was 440 W/kg under AM1.5 and 540 W/kg under AM0.

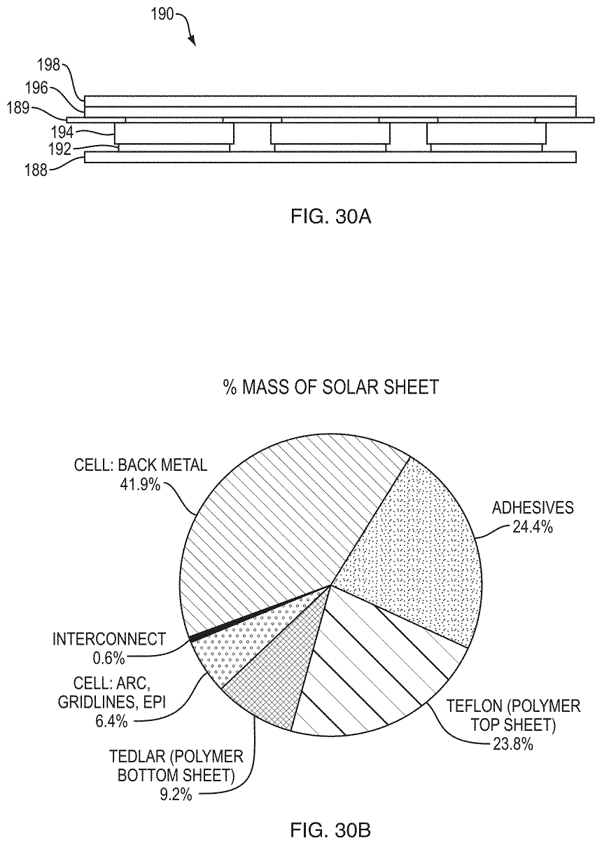

The layers of example solar sheet A generally corresponded to the layers of solar sheet 90 described above with respect to FIGS. 23A and 23B except with the addition of a polymer bottom sheet underlying the first adhesive layer. FIG. 30A shows the layers of example solar sheet A 190. Specifically, example solar sheet A 192 included a plurality of solar cells 194 each having a top surface and a bottom surface. Example solar sheet A 192 included a first adhesive layer in contact with the bottom surface of each solar cell 194. Example solar sheet A 190 also included a second adhesive layer 196 in contact with the top surface of each of the plurality of solar cells 194. Example solar sheet A 190 included a first polymer layer 198, which may be described as a polymer top sheet, attached to the second adhesive layer 196, and a second polymer layer 188, which may be described as a polymer bottom sheet, attached to the first adhesive layer 192. The solar sheet also included interconnects 189 between the solar cells 194 and the second adhesive layer 196.

Table 1 below lists the different layers of example solar sheet A and the materials used for each layer. In addition, Table 1 shows the areal mass of each layer and contribution of the mass of each layer to the total mass. FIG. 30B graphically illustrates how the mass of each layer contributes to the total mass of the solar sheet A.

TABLE 1
Layers of Example Solar Sheet A

| | Mass/Area | |
|---|---|---|
| | of Solar | % Mass |
| | Sheet | of Solar |
| Layer | (g/m²) | Sheet |
| Polymer Top Sheet-TEFLON | 122 | 23.8% |
| Second Adhesive Layer-NT 1001 | 62 | 12.2% |
| Interconnects-Tabs | 3 | 0.6% |
| Solar Cell excluding metal backing | 33 | 6.4% |
| layer | | |
| Metal Backing Layer of solar cell | 214 | 41.9% |
| First Adhesive Layer-NT 1001 | 62 | 12.2% |
| Polymer bottom Sheet-TEDLAR | 47 | 9.2% |
| TOTAL | 543 | |

### Example Solar Sheet B

The inventors made and tested an improved solar sheet having a planar coversheet (e.g., devoid of prismatic structures such as polymer layer 98 shown in FIG. 23B), and identified as example solar sheet B herein. The layer structure of example solar sheet B corresponds to that shown in FIGS. 23A and 23B and described above. The solar cells used in example solar sheet B were flexible and triple-junction AlInGaP/GaAs/InGaAs inverted metamorphic (IMM) solar cells made using an ELO process. Specifically, the cell included an AlInGaP top cell, a GaAs middle cell and an InGaAs bottom cell overlaying a metal backing layer.

The specific power of example solar sheet B was significantly increased as compared to that of example solar sheet A. In order to decrease the areal mass of the solar sheet, the inventors reduced the thickness of the polymer layer top sheet, omitted the polymer bottom sheet and reduced the thickness of metal backing layer in the solar cells. More specifically, the inventors reduced the thickness of the top polymer layer (i.e., the TEFLON sheet), from about 50 microns (as in solar sheet A) to about 25 microns. The thicknesses of the first and second adhesive layers were reduced from 25 micron to 12 microns. In addition, the thickness of the metal backing layer in the solar cells was reduced from 25 to 13 microns. The areal mass was about 240 g/m². The areal power of solar sheet was measured to be about 260 W/m² under AM1.5 and 330 W/m² under AM0. The specific power of example solar sheet B was 1080 W/kg under AM1.5 and 1380 W/kg under AM0; this is a significant increase over the specific power of example solar sheet A. As the thickness of the solar cells and solar sheets was reduced, it became more challenging to handle the solar cells and components of solar sheets during the assembly of the solar sheets. For example, due to the reduction in thickness, various components of the solar sheet tended to curl easily, increasing the difficulties in making the solar sheets.

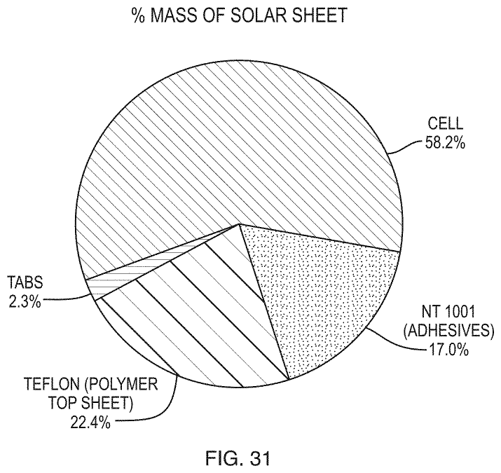

Table 2 shows the different layers of example solar sheet B and the materials used for each layer. In addition, Table 2 shows the areal mass of each layer and the contribution of the mass of each layer to the total mass. FIG. 31 graphically illustrates how the mass of each layer contributes to the total mass of example solar sheet B.

TABLE 2
Layers of Example Solar Sheet B

| | Mass/Area | |
|---|---|---|
| | of Solar | % Mass |
| | Sheet | of Solar |
| Layer | (g/m²) | Sheet |
| Polymer Top Sheet-TEFLON | 52.5 | 9.9% |
| Second Adhesive Layer-NT 1001 | 20.0 | 3.8% |
| Interconnects-Tabs | 5.5 | 1.0% |
| Solar Cell | 136.5 | 25.8% |
| First Adhesive Layer-NT 1001 | 20.0 | 3.8% |
| TOTAL | 234.5 | |

Example Solar Sheet C with Frame Adhesive Layer

Example solar sheet C having a planar coversheet (e.g., devoid of prismatic structures such as sheet 98 shown in FIG. 23B). The solar sheet C include a first adhesive layer including cutouts as shown in FIG. 29A and described above. The structure of the layers of the solar sheet is shown in FIG. 23A and described above. The solar cells in example solar sheet C are flexible and triple-junction AlInGaP/GaAs/InGaAs inverted metamorphic (IMM) solar cells made using an ELO process. Specifically, the cell includes an AlInGaP top cell, a GaAs middle cell and an InGaAs bottom cell overlaying a metal backing layer. Rather than a continuous layer of adhesive between the bottom surface of the plurality of solar cells and the surface to which the solar sheet is to be adhered, example solar sheet C employs cutouts corresponding to the position of each solar cell to greatly decrease the amount of adhesive used and the total mass of the adhesive used for the second adhesive layer. In this example, 90% of the adhesive material is removed. Further, the thickness of the metal backing layer is reduced to 5 microns for each solar cell. The areal power of the solar sheet is 290 W/m² under AM1.5 and 3700 W/m² under AM0. Example solar sheet C has increased specific power as compared to example solar sheet A and example solar sheet B. The specific power of the solar sheet is 1810 W/kg under AM1.5 and 2310 W/kg under AM0.

Although some embodiments are described herein with respect to battery-powered UAVs, one of ordinary skill in the art will recognize that this disclosure also applies to UAVs incorporating other types of devices for storing electrical energy (e.g., fuel cells). Thus, kits and methods for increasing the endurance of electrically-powered UAVs (e.g., fuel-cell powered UAVs, battery-powered UAVs) fall within the scope of this disclosure.

While the present invention has been described with reference to illustrative embodiments thereof, those skilled in the art will appreciate that various changes in form in detail may be made without parting from the intended scope of the present invention as defined in the appended claims.

As may be recognized by those of ordinary skill in the pertinent art based on the teachings herein, numerous changes and modifications may be made to the above-described and other embodiments of the present disclosure without departing from the spirit of the invention as defined in the appended claims. Accordingly, this detailed description of embodiments is to be taken in an illustrative, as opposed to a limiting, sense. Those skilled in the art will recognize, or be able to ascertain using no more than routine experimentation, many equivalents to the specific embodiments of the described herein. Such equivalents are intended to be encompassed by the following claims.

1. A solar sheet, comprising:
a plurality of thin film solar cells; and
a flexible polymer sheet overlaying a light receiving surface of the plurality of thin film solar cells, a bottom surface of the flexible polymer sheet faces the plurality of thin film solar cells and a top surface of the flexible polymer sheet forms an air-material interface of the solar sheet, the top surface having a plurality of prismatic structures operative to refract light towards the plurality of solar cells.

2. The solar sheet of claim 1, wherein the plurality of prismatic structures are configured to recapture light reflected from a surface of a thin film solar cell in the plurality of thin film solar cells.

3. The solar sheet of claim 1, wherein a light collection efficiency of the solar sheet for light at a zenith angle of 75° is greater than 90%.

4. The solar sheet of claim 1, wherein the flexible polymer sheet has a thickness in a range from 25 micrometers to 150 micrometers.

5. The solar sheet of claim 1, wherein a height of each prismatic structure in the plurality of prismatic structures is in a range from 10 micrometers to 100 micrometers.

6. The solar sheet of claim 1, wherein the flexible polymer sheet is formed of a fluoropolymer.

7. The solar sheet of claim 6, wherein the fluoropolymer comprises at least one from the group of fluorinated ethylene propylene (FEP), ethylene tetrafluoroethylene (ETFE), ethylene chlorotrifluoroethylene (ECTFE), and polychlorotrifluoroethylene (PCTFE).

8. The solar sheet of claim 1, wherein the flexible polymer sheet is formed of silicone.

9. The solar sheet of claim 1, wherein the plurality of prismatic structures includes inverted prism structures or prism structures that project outward from the top surface.

10. The solar sheet of claim 9, wherein each prism structure is a linear or curvilinear prism.

11. The solar sheet of claim 9, wherein each prism structure is a corner cube prism.

12. The solar sheet of claim 9, wherein each prism structure is a pyramidal prism.

13. The solar sheet of claim 1, wherein the plurality of prismatic structures is configured to increase a conversion efficiency of the plurality of solar cells for light at a zenith angle between 0° and 20°.

14. The solar sheet of claim 1, wherein a sidewall angle of each prismatic structure is in a range from 15 to 75 degrees.

15. The solar sheet of claim 14, wherein the sidewall angle is in a range from 45 degrees to 60 degrees.

16. The solar sheet of claim 1, wherein the flexible polymer sheet is configured to encapsulate the light receiving surface of the plurality of solar cells.

17. The solar sheet of claim 1, wherein a specific power of the solar sheet is in a range from 1000 W/kg to 4500 W/kg.

18. The solar sheet of claim 1, wherein a characteristic dimension of each prismatic structure in the plurality of prismatic structures is greater than a wavelength of incident light.

19. The solar sheet of claim 1, wherein a characteristic dimension of each prismatic structure in the plurality of prismatic structures is less than a wavelength of incident light.

20. The solar sheet of claim 19, wherein a characteristic dimension of each prismatic structure in the plurality of prismatic structures is less than 500 micrometers.

21. The solar sheet of claim 1, wherein the flexible polymer sheet can be flexed in two dimensions to a bend radius of 1 centimeter.

22. The solar sheet of claim 1, wherein a transmissivity of the solar sheet for light at a wavelength of 400 nm and 1500 nm is greater than 85%.

23. The solar sheet of claim 1, further comprising an adhesive connecting the plurality of solar cells to the flexible polymer sheet.

24. The solar sheet of claim 23, wherein the adhesive is a silicone-based, pressure-sensitive adhesive layer.

25. The solar sheet of claim 1, wherein solar sheet is configured for installation ern a surface of an unmanned aerial vehicle (UAV) or on a surface of a component of a UAV.

26-31. (canceled)

32. A method of improving flight time in an unmanned aerial vehicle (UAV), comprising:
providing a solar sheet according to claim 1;
providing a power conditioning system configured to operate the solar sheet within a desired power range and configured to provide power in the form of a voltage compatible with an electrical system of the UAV;
installing the solar sheet to the UAV; and
connecting the power conditioning system with the electrical system of the UAV.

33. An unmanned aerial vehicle (UAV), comprising:
a solar sheet according to claim 1 installed on a surface of the UAV or on a surface of a component of the UAV; and
a power conditioning system configured to operate the solar sheet within a desired power range and configured to provide power in the form of a voltage compatible with an electrical system of the UAV.
